(19) United States
(12) Patent Application Publication
(10) Pub. No.: US 2025/0143124 A1
(43) Pub. Date: May 1, 2025

(54) DISPLAY APPARATUS

(71) Applicant: Samsung Display Co., LTD., Yongin-si (KR)

(72) Inventors: Seungjun LEE, Yongin-si (KR); Seunghwan CHO, Yongin-si (KR); Taeho KIM, Yongin-si (KR); Yongsu LEE, Yongin-si (KR); Jaewoo LEE, Yongin-si (KR)

(21) Appl. No.: 18/930,792

(22) Filed: Oct. 29, 2024

(30) Foreign Application Priority Data
Oct. 30, 2023 (KR) 10-2023-0147151

(51) Int. Cl. H10K 59/131; H10K 59/35

(52) U.S. Cl. CPC H10K 59/131; H10K 59/352; H10K 59/353

(57) ABSTRACT

A display apparatus includes a first first sub-pixel and a first third sub-pixel at two vertices adjacent in a row direction of an imaginary quadrangle centered on a first second sub-pixel, and first first, first second, and first third light-emitting diodes respectively corresponding to the first first, first second, and first third sub-pixels. The first first, first second, and first third light-emitting diodes are respectively connected to first first, first second, and first third driving circuits via first first, first second, and first third via connection metals. A first contact of the first first light-emitting diode and the first first via connection metal is between the first first and the first third sub-pixels adjacent in the row direction, and a second contact of the first second light-emitting diode and the first second via connection metal is between the first first and a second third sub-pixels adjacent in the column direction.

This application claims priority to Korean Patent Application No. 10-2023-0147151, filed on Oct. 30, 2023, and all the benefits accruing therefrom under 35 U.S.C. § 119, the content of which in its entirety is herein incorporated by reference.

### BACKGROUND

### 1. Field

One or more embodiments relate to display apparatuses.

### 2. Description of the Related Art

With the advancement of display apparatuses that visually display electrical signals, various display apparatuses with desired characteristics such as thinness, lightness, and low power consumption have been introduced. As a proportion occupied by a display area capable of providing an image in a display apparatus has increased, a peripheral area, which is a dead space in which light-emitting diodes are not arranged, is reduced.

### SUMMARY

In display apparatuses, where a peripheral area is reduced to increase a proportion occupied by a display area, a space in which elements arranged in the peripheral area are positioned has been reduced, such that the quality of light emitted from the light-emitting diodes may deteriorate.

One or more embodiments include a display apparatus capable of providing high-resolution and high-quality images.

According to one or more embodiments, a display apparatus includes first sub-pixels, second sub-pixels, and third sub-pixels arranged in a display area to emit light of different colors from each other, wherein a first first sub-pixel, which is one of the first sub-pixels, and a first third sub-pixel, which is one of the third sub-pixels, are respectively arranged at two vertices adjacent to each other in a row direction from among vertices of an imaginary quadrangle centered on a first second sub-pixel, which is one of the second sub-pixels, a first first light-emitting diode, a first second light-emitting diode, and a first third light-emitting diode respectively corresponding to the first first sub-pixel, the first second sub-pixel, and the first third sub-pixel, a first first driving circuit electrically connected to the first first light-emitting diode and including a transistor electrically connected to a first data line which extends in a column direction crossing the row direction, a first second driving circuit electrically connected to the first second light-emitting diode and including a transistor electrically connected to a second data line which extends in the column direction, a first third driving circuit electrically connected to the first third light-emitting diode and including a transistor electrically connected to a third data line which extends in the column direction, a first first via connection metal which electrically connects a first electrode of the first first light-emitting diode and the first first driving circuit to each other, a first second via connection metal which electrically connects a first electrode of the first second light-emitting diode and the first second driving circuit to each other, and a first third via connection metal which electrically connects a first electrode of the first third light-emitting diode and the first third driving circuit to each other. In such an embodiment, a first contact of the first electrode of the first first light-emitting diode and the first first via connection metal is positioned between the first first sub-pixel and the first third sub-pixel adjacent to each other in the row direction, and a second contact of the first electrode of the first second light-emitting diode and the first second via connection metal is positioned between the first first sub-pixel and a second third sub-pixel adjacent to the first first sub-pixel in the column direction.

According to one or more embodiments, a display apparatus includes a first data line, a second data line, and a third data line, where each of the first data line, the second data line, and the third data line extends in a column direction, first driving circuits arranged in the column direction and electrically connected to the first data line, second driving circuits arranged in the column direction and electrically connected to the second data line, third driving circuits arranged in the column direction and electrically connected to the third data line, a first first light-emitting diode electrically connected to a first first driving circuit, which is one of the first driving circuits, where the first first light-emitting diode emits light of a first color, a second first light-emitting diode electrically connected to a second first driving circuit, which is another of the first driving circuits, where the second first light-emitting diode emits light of the first color, a first second light-emitting diode electrically connected to a first second driving circuit, which is one of the second driving circuits, where the first second light-emitting diode emits light of a second color, and a first third light-emitting diode electrically connected to a first third driving circuit, which is one of the third driving circuits, where the first third light-emitting diode emits light of a third color. In such an embodiment, the first first light-emitting diode, the second first light-emitting diode, and the first third light-emitting diode are positioned at vertices of an imaginary quadrangle centered on the first second light-emitting diode, the first first light-emitting diode and the second first light-emitting diode are arranged in a diagonal direction of the imaginary quadrangle with the first second light-emitting diode therebetween, the first third light-emitting diode is arranged adjacent to the first first light-emitting diode in a row direction crossing the column direction, and the first first driving circuit and the second first driving circuit are adjacent to each other in the column direction.

According to one or more embodiments, a display apparatus includes a first first light-emitting diode and a second first light-emitting diode, which emit light of a first color, a first second light-emitting diode which emits light of a second color, a first third light-emitting diode which emits light of a third color, a first first driving circuit electrically connected to a first data line which extends in a column direction, wherein the first first driving circuit comprises transistors, a first insulating layer disposed on an electrode electrically connected to a semiconductor layer of one transistor from among the transistors of the first first driving circuit, a connection metal disposed on the first insulating layer and electrically connected to the electrode, a second insulating layer on the connection metal, a first first via connection metal disposed on the second insulating layer and electrically connected to the connection metal, and a third insulating layer on the first first via connection metal. In such an embodiment, the first first light-emitting diode, the second first light-emitting diode, and the first third light-emitting diode are positioned at vertices of an imaginary quadrangle centered on the first second light-emitting diode, the first first light-emitting diode and the second first light-emitting diode are arranged in a diagonal direction of the imaginary quadrangle with the first second light-emitting diode therebetween, the first third light-emitting diode is arranged adjacent to the first first light-emitting diode in a row direction crossing the column direction, the first first driving circuit is adjacent to a second first driving circuit in the column direction, and the second first driving circuit is electrically connected to the second first light-emitting diode.

### BRIEF DESCRIPTION OF THE DRAWINGS

The above and other features of certain embodiments of the disclosure will be more apparent from the following description taken in conjunction with the accompanying drawings, in which:

FIG. 1 is a plan view schematically illustrating a display apparatus according to an embodiment;

FIG. 2 is a side view schematically illustrating the display apparatus shown in FIG. 1;

FIG. 3 is an equivalent circuit diagram of a sub-pixel according to an embodiment;

FIG. 4 is a cross-sectional view illustrating part of a display area of a display apparatus according to an embodiment;

FIG. 5A is a plan view schematically illustrating an arrangement of sub-pixels arranged in a display area of a display apparatus, according to an embodiment;

FIG. 5B is a plan view schematically illustrating an arrangement of light-emitting diodes arranged in a display area of a display apparatus, according to an embodiment;

FIG. 6A is a plan view illustrating driving circuits arranged in a display area of a display apparatus, lines electrically connected to the driving circuits, and light-emitting diodes, according to an embodiment;

FIG. 6B is a plan view illustrating light-emitting diodes and via connection metals that are arranged in the display area of the display apparatus shown in FIG. 6A, according to an embodiment;

FIG. 6C is a plan view illustrating light-emitting diodes and via connection metals that are arranged in a display area of a display apparatus, according to an embodiment;

FIG. 7A is a plan view illustrating driving circuits arranged in a display area of a display apparatus, lines electrically connected to the driving circuits, and light-emitting diodes, according to an embodiment; and

FIG. 7B is a plan view illustrating light-emitting diodes and via connection metals that are arranged in the display area of the display apparatus shown in FIG. 7A, according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

One or more embodiments of the disclosure will be described below in more detail with reference to the accompanying drawings. Those elements that are the same or are in correspondence are rendered the same reference numeral regardless of the figure number, and redundant descriptions thereof are omitted.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated or reduced for convenience of explanation. In other words, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or element is referred to as being “connected” to another layer, region, or element, it may be “directly connected” to the other layer, region, or element and/or may be “indirectly connected” to the other layer, region, or element with other layer, region, or element therebetween. For example, it will be understood that when a layer, region, or element is referred to as being “electrically connected” to another layer, region, or element, it may be “directly electrically connected” to the other layer, region, or element and/or may be “indirectly electrically connected” to other layer, region, or element with other layer, region, or element therebetween.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings, where the same or corresponding elements are denoted by the same reference numerals throughout, and any repetitive detailed description thereof may be omitted or simplified.

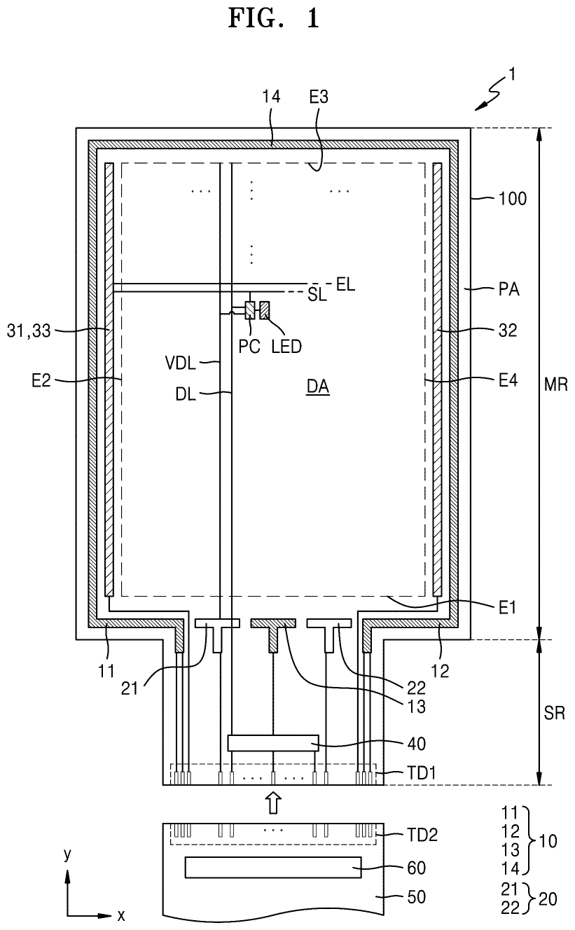

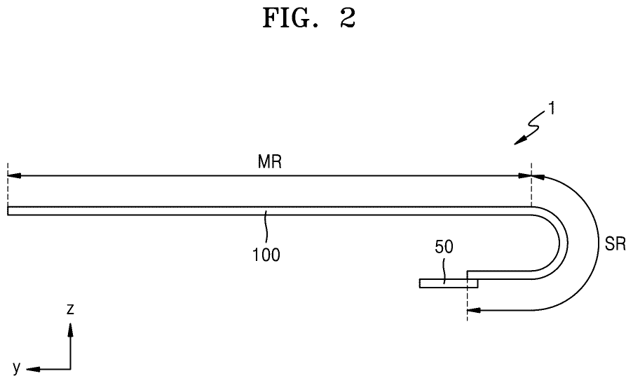

FIG. 1 is a plan view schematically illustrating a display apparatus 1 according to an embodiment, and FIG. 2 is a side view schematically illustrating the display apparatus 1 shown in FIG. 1.

Referring to FIGS. 1 and 2, an embodiment of the display apparatus 1 may be an electronic device with a display screen in various products, such as smartphones, tablets, laptops, televisions, or advertisement boards.

In an embodiment, the display apparatus 1 may include a display area DA and a peripheral area PA outside the display area DA. The display area DA is a portion in which an image is displayed, and may provide images through a plurality of pixels. Each of the pixels may include sub-pixels emitting light of different colors from each other. In an embodiment, for example, the sub-pixels may emit red, green, or blue light through light-emitting diodes LED.

When viewed from a direction approximately perpendicular to the display apparatus 1 (i.e., a direction perpendicular to x direction and y direction), the display apparatus 1 may have various shapes, such as a circular shape, an oval shape, a polygon shape, or a specific shape. In FIG. 1, the display area DA has an approximately quadrangular shape. However, in another embodiment, the display area DA may have an approximately quadrangular shape with round edges.

The peripheral area PA may be arranged outside the display area DA. The peripheral area PA may entirely surround the display area DA. A portion of the peripheral area PA (hereinafter, referred to as a protruding peripheral area) may extend in a direction away from the display area DA (e.g., −y direction). In other words, the display apparatus 1 may include the display area DA, a main area MR including a portion of the peripheral area PA surrounding the display area DA, and a sub-area SR extending from the main area MR in one direction, and the sub-area SR may correspond to the protruding peripheral area described above. A width of the sub-area SR (e.g., a width in ±x directions) may be less than a width of the main area MR (e.g., a width in ±x directions), and a portion of the sub-area SR may be bent, as shown in FIG. 2. In a state where the display apparatus 1 is bent, as shown in FIG. 2, the peripheral area PA, which is a non-display area when the display apparatus 1 is viewed, may not be visible, or, even when the peripheral area PA is visible, a visible area may be minimized.

A shape of the display apparatus 1 described above may be substantially identical to a shape of a substrate 100 therein. In an embodiment, for example, the substrate 100 may also include the display area DA and the peripheral area PA. In an embodiment, for example, the substrate 100 may also include the main area MR and the sub-area SR.

The light-emitting diode LED is arranged in the display area DA and may emit red, green, or blue light. The light-emitting diode LED may be an organic light-emitting diode, an inorganic light-emitting diode, or a quantum dot light-emitting diode.

The light-emitting diode LED may be electrically connected to a circuit for driving light-emitting diodes (hereinafter, referred to as a driving circuit) PC. The driving circuit PC may include transistors electrically connected to a signal line or a voltage line, which are for controlling turn on/off of the light-emitting diode LED. In an embodiment, as shown in FIG. 1, a scan line SL, an emission control line EL, and a data line DL may be provided as signal lines electrically connected to transistors, and a vertical driving voltage line VDL may be provided as a voltage line. In the peripheral area PA, a common voltage supply line 10, a driving voltage supply line 20, first and second scan driving circuits 31 and 32, an emission control driving circuit 33, and a data driving circuit 40 may be arranged.

The common voltage supply line 10 may be arranged in the peripheral area PA. The common voltage supply line 10 may include a first common voltage input unit 11, a second common voltage input unit 12, and a third common voltage input unit 13, which are arranged adjacent to a first edge E1 of the display area DA. The first common voltage input unit 11 and the second common voltage input unit 12 may be offset from each other, and the third common voltage input unit 13 may be positioned between the first common voltage input unit 11 and the second common voltage input unit 12. The third common voltage input unit 13 may be offset from the first common voltage input unit 11 and the second common voltage input unit 12. The first common voltage input unit 11 and the second common voltage input unit 12 may be respectively arranged at opposite ends of the first edge E1 of the display area DA, and the third common voltage input unit 13 may be arranged in the middle of the first edge E1 of the display area DA.

The first common voltage input unit 11 and the second common voltage input unit 12 may be connected to a body unit 14, which extends along a second edge E2, a third edge E3, and a fourth edge E4 of the display area DA. In an embodiment, the first common voltage input unit 11, the second common voltage input unit 12, and the body unit 14 may be integrally connected to each other or integrally formed with each other as a single unitary indivisible part.

The driving voltage supply line 20 may be arranged in the peripheral area PA and electrically connected to the vertical driving voltage line VDL, which crosses the display area DA in a column direction (e.g., the ±y directions). In an embodiment, the driving voltage supply line 20 may include first and second driving voltage input units 21 and 22 at opposite sides with the third common voltage input unit 13 therebetween.

In an embodiment, as shown in FIG. 1, the common voltage supply line 10 includes the third common voltage input unit 13 between the first and second common voltage input units 11 and 12. However, one or more embodiments are not limited thereto. In another embodiment, the third common voltage input unit 13 may be omitted, and the first and second driving voltage input units 21 and 22 may be integrally connected to each other.

The first and second scan driving circuits 31 and 32 may be arranged in the peripheral area PA and electrically connected to the scan line SL. In an embodiment, some of the scan lines SL may be electrically connected to the first scan driving circuit 31, and the remaining ones may be electrically connected to the second scan driving circuits 32. The first and second scan driving circuits 31 and 32 may generate scan signals, and the generated scan signals may be transmitted through the scan line SL to a transistor electrically connected to a light-emitting diode LED.

The emission control driving circuit 33 may be arranged on a side of the first scan driving circuit 31 and may transmit an emission control signal to a transistor electrically connected to the light-emitting diode LED. In an embodiment, as shown in FIG. 1, the emission control driving circuit 33 is arranged at one side of the display area DA. Similar to the first scan driving circuit 31 and the second scan driving circuits 32, the emission control driving circuit 33 may be arranged at opposite sides of the display area DA with the display area DA therebetween.

The data driving circuit 40 may be arranged in the sub-area SR. The data driving circuit 40 may transmit a data signal through the data line DL to a transistor electrically connected to the light-emitting diode LED.

A first terminal unit TD1 may be positioned on one side of the substrate 100, for example, at one end of the sub-area SR. A printed circuit board 50 may be attached onto the first terminal unit TD1. The printed circuit board 50 may include a second terminal unit TD2 electrically connected to the first terminal unit TD1, and a controller 60 may be disposed on the printed circuit board 50. Control signals of the controller 60 may be respectively provided to the first and second scan driving circuits 31 and 32, the emission control driving circuit 33, the data driving circuit 40, the driving voltage supply line 20, and the common voltage supply line 10 through the first and second terminal units TD1 and TD2.

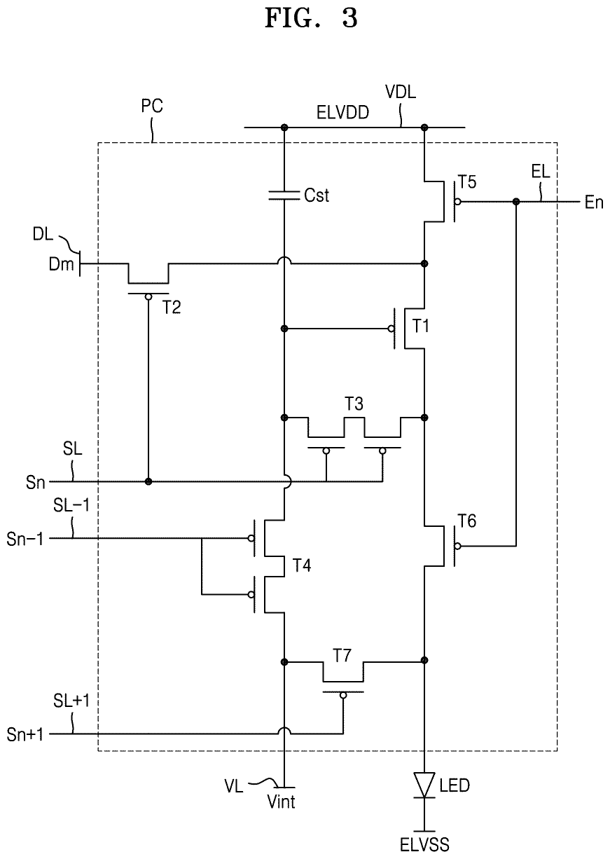

FIG. 3 is an equivalent circuit diagram of a sub-pixel according to an embodiment.

Referring to FIG. 3, in an embodiment, a driving circuit PC of a sub-pixel may include a driving transistor T1, a data write transistor T2, a compensation transistor T3, a first initialization transistor T4, an operation control transistor T5, an emission control transistor T6, a second initialization transistor T7, and a storage capacitor Cst.

In an embodiment, as shown in FIG. 3, signal lines SL, SL−1, SL+1, EL, and DL, an initialization voltage line VL, and a vertical driving voltage line VDL are provided in or connected to each driving circuit PC. However, one or more embodiments are not limited thereto. In another embodiment, the initialization voltage line VL and/or at least one of the signal lines SL, SL−1, SL+1, EL, or DL may be shared among neighboring driving circuits PC.

A drain electrode of the driving transistor T1 may be electrically connected to the light-emitting diode LED via the emission control transistor T6. The driving transistor T1 may receive a data signal Dm based on a switching operation of the data write transistor T2 and supply a driving current to the light-emitting diode LED.

A gate electrode of the data write transistor T2 may be electrically connected to the scan line SL, and a source electrode thereof may be electrically connected to the data line DL. A drain electrode of the data write transistor T2 may be electrically connected to the vertical driving voltage line VDL via the operation control transistor T5 and electrically connected to the source electrode of the driving transistor T1.

The data write transistor T2 may be turned on in response to a scan signal Sn received via the scan line SL and may perform a switching operation for transferring the data signal Dm received via the data line DL to the source electrode of the driving transistor T1.

A gate electrode of the compensation transistor T3 may be electrically connected to the scan line SL. A source electrode of the compensation transistor T3 may be electrically connected to a first electrode (e.g., an anode or a pixel electrode) of the light-emitting diode LED via the emission control transistor T6 and electrically connected to the drain electrode of the driving transistor T1. A drain electrode of the compensation transistor T3 may be electrically connected to one electrode of the storage capacitor Cst, a source electrode of the first initialization transistor T4, and the gate electrode of the driving transistor T1. The compensation transistor T3 may be turned on in response to a scan signal Sn received via the scan line SL to electrically connect the gate electrode of the driving transistor T1 to the drain electrode of the driving transistor T1, to diode-connect the driving transistor T1.

A gate electrode of the first initialization transistor T4 may be electrically connected to a previous scan line SL−1. A drain electrode of the first initialization transistor T4 may be electrically connected to the initialization voltage line VL. A source electrode of the first initialization transistor T4 may be electrically connected to the one electrode of the storage capacitor Cst, the drain electrode of the compensation transistor T3, and the gate electrode of the driving transistor T1. The first initialization transistor T4 may be turned on according to a previous scan signal Sn−1 received via the previous scan line SL−1 and may transfer an initialization voltage Vint to the gate electrode of the driving transistor T1 to perform an initialization operation for initializing a voltage of the gate electrode of the driving transistor T1.

A gate electrode of the operation control transistor T5 may be electrically connected to the emission control line EL. A source electrode of the operation control transistor T5 may be electrically connected to the vertical driving voltage line VDL. A drain electrode of the operation control transistor T5 may be electrically connected to the source electrode of the driving transistor T1 and the drain electrode of the data write transistor T2.

A gate electrode of the emission control transistor T6 may be electrically connected to the emission control line EL. A source electrode of the emission control transistor T6 may be electrically connected to the drain electrode of the driving transistor T1 and a source electrode of the compensation transistor T3. A drain electrode of the emission control transistor T6 may be electrically connected to the first electrode (e.g, the anode or the pixel electrode) of the light-emitting diode LED. The operation control transistor T5 and the emission control transistor T6 may be simultaneously turned on in response to an emission control signal En received via the emission control line EL, such that a first power voltage ELVDD is transferred to the light-emitting diode LED, and a driving current flows through the light-emitting diode LED.

A gate electrode of the second initialization transistor T7 may be electrically connected to a next scan line SL+1. A source electrode of the second initialization transistor T7 may be electrically connected to the first electrode (e.g., the anode or the pixel electrode) of the light-emitting diode LED. A drain electrode of the second initialization transistor T7 may be electrically connected to the initialization voltage line VL. The second initialization transistor T7 may be turned on in response to a next scan signal Sn+1 received via the next scan line SL+1 to initialize the first electrode (e.g, the anode or the pixel electrode) of the light-emitting diode LED.

In an embodiment, as shown in FIG. 3, the first initialization transistor T4 and the second initialization transistor T7 are connected to the previous scan line SL−1 and the next scan line SL+1, respectively. However, one or more embodiments are not limited thereto. In another embodiment, both the first initialization transistor T4 and the second initialization transistor T7 may be electrically connected to the previous scan line SL−1 to be driven according to the previous scan signal Sn−1.

The one electrode of the storage capacitor Cst may be electrically connected to the gate electrode of the driving transistor T1, the drain electrode of the compensation transistor T3, and the source electrode of the first initialization transistor T4. Another electrode of the storage capacitor Cst may be electrically connected to the vertical driving voltage line VDL.

A second electrode (e.g., a cathode) of the light-emitting diode LED may receive a common voltage ELVSS. The light-emitting diode LED may receive a driving current from the driving transistor T1 to emit light. For example, the second electrode (e.g., the cathode) of the light-emitting diode LED may be electrically connected to the common voltage supply line 10 described with reference to FIG. 1.

The driving circuit PC is not limited to the number and circuit design of transistors and storage capacitors described with reference to FIG. 3, and the number and circuit design may be modified in various ways.

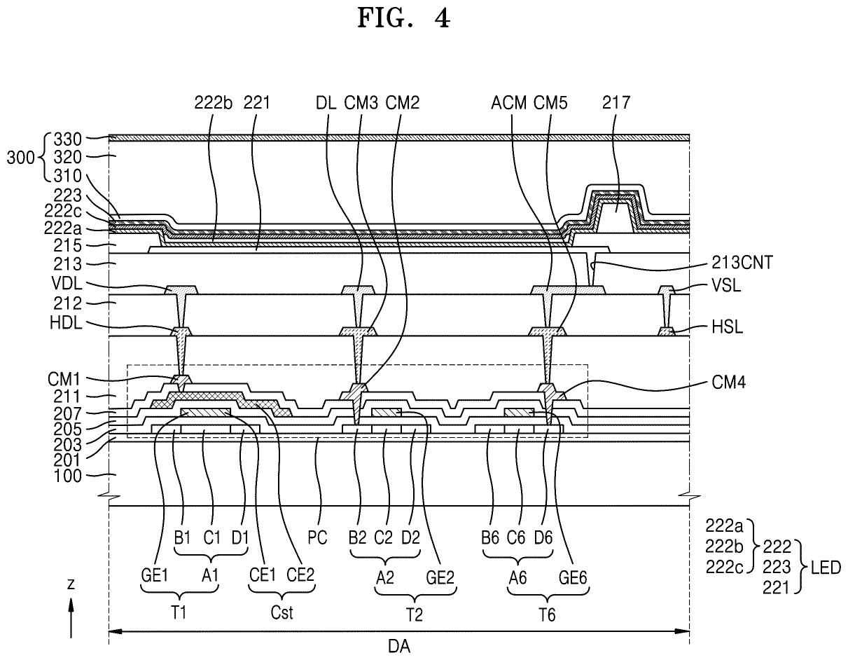

FIG. 4 is a cross-sectional view illustrating part of a display area DA of a display apparatus according to an embodiment.

Referring to FIG. 4, in an embodiment, a light-emitting diode LED is arranged in the display area DA, and the light-emitting diode LED may be electrically connected to a driving circuit PC in a direction perpendicular to the substrate 100 (e.g., a +z direction). In such an embodiment, the driving circuit PC may be disposed between the substrate 100 and the light-emitting diode LED.

The substrate 100 may include a glass material or polymer resin. In an embodiment, the substrate 100 may have an alternate stack structure of a base layer including polymer resin and a barrier layer including an inorganic insulating material such as silicon oxide or silicon nitride. Polymer resin may include polyethersulfone, polyarylate, polyetherimide, polyethylene naphthalate, polyethylene terephthalate, polyphenylene sulfide, polyimide, polycarbonate, cellulose triacetate, cellulose acetate propionate, etc.

Before the driving circuit PC is formed, a buffer layer 201 may be formed on the substrate 100 to prevent permeation of impurities into the driving circuit PC. The buffer layer 201 may include an inorganic insulating material such as silicon nitride, silicon oxynitride, and/or silicon oxide, and may include a single-layer or multi-layer structure, each layer therein including at least one selected from the inorganic insulating materials described above.

The driving circuit PC may include a plurality of transistors and a storage capacitor described above with reference to FIG. 3, and regarding this, FIG. 4 shows a driving transistor T1, a data write transistor T2, an emission control transistor T6, and a storage capacitor Cst.

The driving transistor T1 may include a semiconductor layer (hereinafter, referred to as “driving semiconductor layer”) A1 on the buffer layer 201, and a driving gate electrode GE1 overlapping a channel region C1 of the driving semiconductor layer A1. The driving semiconductor layer A1 may include a silicon-based semiconductor material, for example, polysilicon. The driving semiconductor layer A1 may include the channel region C1, a first region B1, and a second region D1, where the first region B1 and the second region D1 are respectively arranged at opposite sides of the channel region C1. The first region B1 and the second region D1 are areas including a higher concentration of impurities than the channel region C1, and one of the first region B1 and the second region D1 may correspond to a source area, and a remaining one may correspond to a drain area.

A first gate insulating layer 203 may be arranged between the driving semiconductor layer A1 and the driving gate electrode GE1. The first gate insulating layer 203 may include an inorganic insulating material such as silicon oxide, silicon nitride, or silicon oxynitride, and may include a single-layer or multi-layer structure, each layer therein including at least one selected from the inorganic insulating materials described above.

The driving gate electrode GE1 may include a conductive material, including molybdenum (Mo), aluminum (Al), copper (Cu), or titanium (Ti), and may include a single-layer or multi-layer structure, each layer therein including at least one selected from the materials described above.

The storage capacitor Cst may include a first capacitor electrode CE1 and a second capacitor electrode CE2 that overlap each other. In an embodiment, the first capacitor electrode CE1 of the storage capacitor Cst may include the driving gate electrode GE1. In other words, the driving gate electrode GE1 may include the first capacitor electrode CE1 of the storage capacitor Cst. In an embodiment, for example, the driving gate electrode GE1 and the first capacitor electrode CE1 of the storage capacitor Cst may be formed integrally with each other as a single unitary indivisible part.

A first interlayer insulating layer 205 may be arranged between the first capacitor electrode CE1 and the second capacitor electrode CE2 of the storage capacitor Cst. The first interlayer insulating layer 205 may include an inorganic insulating material such as silicon oxide, silicon nitride, or silicon oxynitride, and may include a single-layer or multi-layer structure, each layer therein including at least one selected from the inorganic insulating materials described above.

The second capacitor electrode CE2 of the storage capacitor Cst may include a low-resistance conductive material such as Mo, Al, Cu, and/or Ti, and may include a single-layer or multi-layer structure, each layer therein including at least one selected from the materials described above.

A second interlayer insulating layer 207 may be disposed on the storage capacitor Cst. The second interlayer insulating layer 207 may include an inorganic insulating material such as silicon oxide, silicon nitride, or silicon oxynitride, and may include a single-layer or multi-layer structure, each layer therein including at least one selected from the inorganic insulating materials described above.

A first connection metal CM1 may be disposed on the second interlayer insulating layer 207 and electrically connected to the second capacitor electrode CE2 via a contact hole defined through the second interlayer insulating layer 207. The first connection metal CM1 may be electrically connected to the vertical driving voltage line VDL.

The vertical driving voltage line VDL may be disposed on a second organic insulating layer 212 and electrically connected to a horizontal driving voltage line HDL. The horizontal driving voltage line HDL may extend in the +x direction in FIG. 1, and the vertical driving voltage line VDL may extend in a direction crossing the horizontal driving voltage line HDL, for example, the ±y direction in FIG. 1. The vertical driving voltage line VDL and/or the horizontal driving voltage line HDL may be electrically connected to the driving voltage supply line 20 described with reference to FIG. 1.

The horizontal driving voltage line HDL may be connected to the first connection metal CM1 via a contact hole defined through a first insulating layer, for example, a first organic insulating layer 211, and the vertical driving voltage line VDL may be connected to the horizontal driving voltage line HDL via a contact hole defined through a second insulating layer, for example, the second organic insulating layer 212. The first organic insulating layer 211 may be disposed on the second interlayer insulating layer 207, and the second organic insulating layer 212 may be disposed on the first organic insulating layer 211. The first organic insulating layer 211 and the second organic insulating layer 212 may include an organic insulating material. The organic insulating material may include benzocyclobutene (BCB), polyimide, or hexamethyldisiloxane (HMDSO). The vertical driving voltage line VDL has a connection structure with the horizontal driving voltage line HDL, thereby effectively preventing a voltage drop due to resistance of the vertical driving voltage line VDL.

A horizontal common voltage line HSL may be disposed on the first organic insulating layer 211, and a vertical common voltage line VSL may be disposed on the second organic insulating layer 212. The vertical common voltage line VSL may be electrically connected to the horizontal common voltage line HSL via a contact hole defined through the second organic insulating layer 212. The horizontal common voltage line HSL may extend in the ±x direction in FIG. 1, and the vertical common voltage line VSL may extend in a direction crossing the horizontal common voltage line HSL, for example, the ±y direction in FIG. 1. The vertical common voltage line VSL and/or the horizontal common voltage line HSL may be electrically connected to the common voltage supply line 10 described above with reference to FIG. 1.

The data write transistor T2 may include a semiconductor layer (hereinafter, referred to as a data write semiconductor layer) A2 on the buffer layer 201, and a data write gate electrode GE2. The data write semiconductor layer A2 may include a silicon-based semiconductor material, for example, polysilicon. The data write semiconductor layer A2 may include a channel region C2, a first region B2, and a second region D2, where the first region B2 and the second region D2 are arranged at opposite sides of the channel region C2. The first region B2 and the second region D2 are areas including a higher concentration of impurities than the channel region C2, and one of the first region B2 and the second region D2 may correspond to a source area, and a remaining one may correspond to a drain area.

The data write semiconductor layer A2 may be connected to the data line DL via a second connection metal CM2 disposed on the second interlayer insulating layer 207 and a third connection metal CM3 disposed on the first organic insulating layer 211. The data line DL may be disposed on the second organic insulating layer 212 and connected to the third connection metal CM3 via a contact hole defined through the second organic insulating layer 212, and the third connection metal CM3 may be connected to the second connection metal CM2 via a contact hole defined through the first organic insulating layer 211.

The emission control transistor T6 may include a semiconductor layer (hereinafter, referred to as an emission control semiconductor layer) A6 on the buffer layer 201, and an emission control gate electrode GE6. The emission control semiconductor layer A6 may include a silicon-based semiconductor material, for example, polysilicon. The emission control semiconductor layer A6 may include the channel region C6, a first region B6, and a second region D6, where the first region B6 and the second region D6 are respectively arranged at opposite sides of the channel region C6. The first region B6 and the second region D6 are areas including a higher concentration of impurities than the channel region C6, and one of the first region B6 and the second region D6 may correspond to a source area, and a remaining one may correspond to a drain area.

The emission control transistor T6 may be electrically connected to a first electrode 221 of the light-emitting diode LED via a fourth connection metal CM4, a fifth connection metal CM5, and a via connection metal ACM.

The fourth connection metal CM4 may be arranged in (or directly on) a same layer in (or directly on) which the first connection metal CM1 and the second connection metal CM2 are arranged, for example, on the second interlayer insulating layer 207. The first connection metal CM1, the second connection metal CM2, and the fourth connection metal CM4 may include aluminum (Al), copper (Cu), and/or titanium (Ti), and may have one or more layers, each including at least one selected from the materials described above.

The fifth connection metal CM5 may be arranged in (or directly on) a same layer in (or directly on) which the third connection metal CM3, the horizontal driving voltage line HDL, and the horizontal common voltage line HSL are arranged, for example, on the first organic insulating layer 211. The fifth connection metal CM5, the third connection metal CM3, the horizontal driving voltage line HDL, and the horizontal common voltage line HSL may include Al, Cu, and/or Ti, and may have one or more layers, each including at least one selected from the materials described above.

The via connection metal ACM may be arranged on the same layer on which the data line DL, the vertical driving voltage line VDL, and the vertical common voltage line VSL are arranged, for example, on the second organic insulating layer 212. The via connection metal ACM, the data line DL, the vertical driving voltage line VDL, and the vertical common voltage line VSL may include Al, Cu, and/or Ti, and may have one or more layers, each including at least one selected from the materials described above.

A third insulating layer, for example, a third organic insulating layer 213, may be disposed on the via connection metal ACM, the data line DL, the vertical driving voltage line VDL, and the vertical common voltage line VSL. The third organic insulating layer 213 may include an organic insulating material such as acryl, BCB, polyimide, and/or HMDSO.

The light-emitting diode LED may be disposed on the third organic insulating layer 213. The first electrode 221 of the light-emitting diode LED may be connected to the via connection metal ACM via a via contact hole 213CNT defined through the third organic insulating layer 213.

The first electrode 221 of the light-emitting diode LED may include a reflective film including silver (Ag), magnesium (Mg), Al, platinum (Pt), palladium (Pd), gold (Au), nickel (Ni), neodymium (Nd), iridium (Ir), chrome (Cr), or any compounds thereof. In another embodiment, the first electrode 221 may further include a conductive oxide layer over and/or under the reflective film described above. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In an embodiment, the first electrode 221 may have a three-layer structure of an ITO layer, an Ag layer, and another ITO layer.

A bank layer 215 may be disposed on the first electrode 221. The bank layer 215 may be provided with an opening that overlaps the first electrode 221, and may cover an edge of the first electrode 221. The bank layer 215 may include an organic insulating material. Alternatively, the bank layer 215 may include a pigment or dye capable of absorbing light.

An intermediate layer 222 may include an emission layer 222b. The intermediate layer 222 may include a first functional layer 222a disposed under the emission layer 222b and/or a second functional layer 222c disposed over the emission layer 222b. The emission layer 222b may include a polymer or low-molecular weight organic material that emits light of a certain color. The second functional layer 222c may include an electron transport layer (ETL) and/or an electron injection layer (EIL). The first functional layer 222a and the second functional layer 222c may include an organic material.

A second electrode 223 may include a conductive material having a low work function. In an embodiment, for example, the second electrode 223 may include a (semi-) transparent layer including Ag, Mg, Al, Pt, Pd, Au, Ni, Nd, Ir, Cr, Li, calcium (Ca), or any alloys thereof. Alternatively, the second electrode 223 may further include a layer such as an ITO layer, an IZO layer, a ZnO layer, or an In₂O₃ layer on the (semi-) transparent layer including the materials described above.

The emission layer 222b may be formed on the display area DA to overlap the first electrode 221 via an opening defined in the bank layer 215. In an embodiment, the first functional layer 222a, the second functional layer 222c, and the second electrode 223 may entirely cover the display area DA.

A spacer 217 may be formed on the bank layer 215. The spacer 217 may be formed together with the bank layer 215 in a same process, or may be individually formed in separate processes. In an embodiment, the spacer 217 may include an organic insulating material such as polyimide.

The light-emitting diode LED may be covered with an encapsulation layer 300. The encapsulation layer 300 may include at least one organic encapsulation layer and at least one inorganic encapsulation layer. In an embodiment, as shown in FIG. 4, the encapsulation layer 300 includes first and second inorganic encapsulation layers 310 and 330 and an organic encapsulation layer 320 located therebetween.

The first inorganic encapsulation layer 310 and the second inorganic encapsulation layer 330 may include at least one inorganic material selected from silicon oxide, silicon nitride, or silicon oxynitride. The first inorganic encapsulation layer 310 and the second inorganic encapsulation layer 330 may include one or more layers, each including at least one selected from the materials described above. The organic encapsulation layer 320 may include a polymer-based material. The polymer-based material may include acryl-based resin, epoxy-based resin, polyimide, and polyethylene. In an embodiment, the organic encapsulation layer 320 may include acrylate.

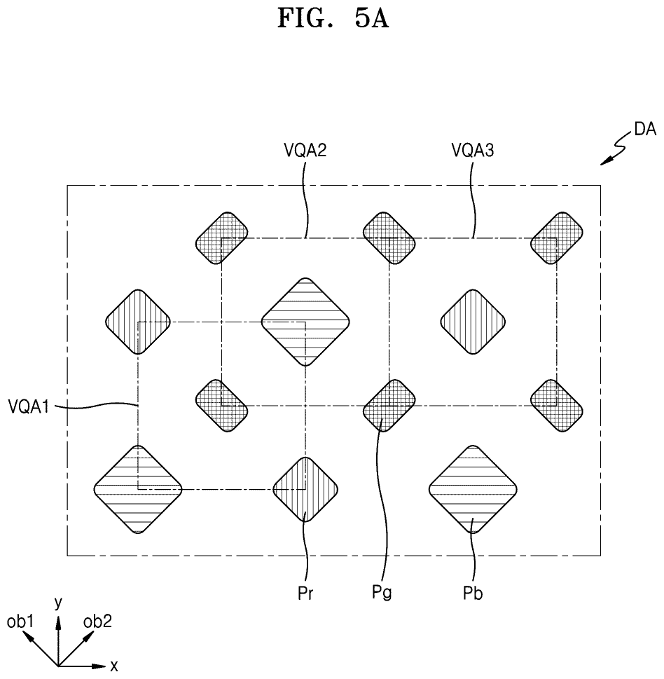

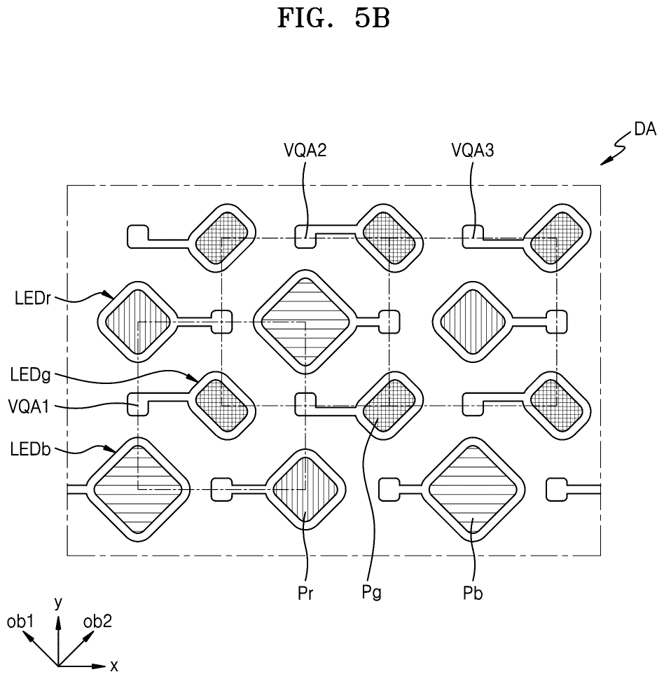

FIG. 5A is a plan view schematically illustrating an arrangement of sub-pixels in a display area DA of a display apparatus according to an embodiment, and FIG. 5B is a plan view schematically illustrating an arrangement of light-emitting diodes in a display area DA of a display apparatus according to an embodiment.

Referring to FIG. 5A, in an embodiment, a first sub-pixel that emits light of a first color, a second sub-pixel that emits light of a second color, and a third sub-pixel that emits light of a third color may be arranged in the display area DA. The first sub-pixel, the second sub-pixel, and the third sub-pixel are sub-pixels that emit light of different colors from each other, and one of the sub-pixels may be a red sub-pixel Pr, another one may be a green sub-pixel Pg, and a remaining one may be a blue sub-pixel Pb. Hereinafter, for convenience of description, embodiments where the first sub-pixel is a red sub-pixel Pr that emits red light, the second sub-pixel is a green sub-pixel Pg that emits green light, and the third sub-pixel is a blue sub-pixel Pb that emits blue light will be described in detail. However, the scope of one or more embodiments is not limited thereto. In another embodiment, the first sub-pixel may be a green or blue sub-pixel, the second sub-pixel may be a red or blue sub-pixel, and the third sub-pixel may be a red or green sub-pixel.

In an embodiment, as shown in FIG. 5A, the red sub-pixel Pr and the blue sub-pixel Pb may be arranged at vertices of a first imaginary quadrangle VQA1 centered on the green sub-pixel Pg. In an embodiment, for example, two red sub-pixels Pr may be respectively arranged at opposite vertices along a first diagonal direction ob1 of the first imaginary quadrangle VQA1 with the green sub-pixel Pg therebetween. Two blue sub-pixels Pb may be respectively arranged at opposite vertices along a second diagonal direction ob2 of the first imaginary quadrangle VQA1 with the green sub-pixel Pg therebetween.

The green sub-pixel Pg may be arranged at vertices of a second imaginary quadrangle VQA2 centered on the blue sub-pixel Pb or vertices of a third imaginary quadrangle VQA3 centered on the red sub-pixel Pr. In an embodiment, as shown in FIG. 5A, four green sub-pixels Pg may be respectively arranged at vertices of the second imaginary quadrangle VQA2 centered on the blue sub-pixel Pb. In such an embodiment, four green sub-pixels Pg may be respectively arranged at vertices of a third imaginary quadrangle VQA3 centered on the red sub-pixel Pr.

Each of the red sub-pixel Pr and the blue sub-pixel Pb may have a quadrangular shape, for example, a diamond shape or a rhombus (e.g., square) shape. The green sub-pixel Pg may have a quadrangular shape, for example, a diamond shape with two sides of different lengths. Two adjacent green sub-pixels Pg from among green sub-pixels Pg arranged in one row or one column may extend in different directions from each other, that is, longitudinal (or length) directions of the two adjacent green sub-pixels Pg are different from each other. In an embodiment, for example, one green sub-pixel Pg arranged in one row direction (e.g., a ±x direction or an extending direction of a scan line SL (see FIG. 1)) or in one column direction (e.g., a ±y direction or an extending direction of a data line DL (see FIG. 1)) may extend in the first diagonal direction ob1, and another green sub-pixel Pg adjacent thereto may extend in the second diagonal direction ob2.

Along one row or in a same row, the green sub-pixel Pg extending in the first diagonal direction ob1 and the green sub-pixel Pg extending in the second diagonal direction ob2 may be alternately arranged. Here, when green sub-pixels Pg are arranged along a row, it may indicate that the green sub-pixels Pg are arranged in the ±x direction. Along one column or in a same column, the green sub-pixel Pg extending in the first diagonal direction ob1 and the green sub-pixel Pg extending in the second diagonal direction ob2 may be alternately arranged. Here, when green sub-pixels Pg are arranged along a column, it may indicate that the green sub-pixels Pg are arranged in the ±y direction.

Along a row adjacent to a row in which the green sub-pixel Pg is arranged, the red sub-pixel Pr and the blue sub-pixel Pb may be alternately arranged. Here, when the red sub-pixel Pr and the blue sub-pixel Pb are arranged along a row, it may indicate that the red sub-pixel Pr and the blue sub-pixel Pb are arranged in the ±x direction. Along a column adjacent to a column in which the green sub-pixel Pg is arranged, the red sub-pixel Pr and the blue sub-pixel Pb may be alternately arranged. Here, when the red sub-pixel Pr and the blue sub-pixel Pb are arranged along a column, it may indicate that the red sub-pixel Pr and the blue sub-pixel Pb are arranged in the ±y direction.

A sub-pixel may emit light of a certain color through a light-emitting diode. Referring to FIG. 5B, in an embodiment, the red sub-pixel Pr may emit red light through a red light-emitting diode LEDr arranged at a corresponding position, the green sub-pixel Pg may emit green light through a green light-emitting diode LEDg arranged at a corresponding position, and the blue sub-pixel Pb may emit blue light through a blue light-emitting diode LEDb arranged at a corresponding position. An emission area of a light-emitting diode may correspond to (or define) a sub-pixel. In an embodiment, for example, an emission area of the red light-emitting diode LEDr may correspond to the red sub-pixel Pr, an emission area of the green light-emitting diode LEDg may correspond to the green sub-pixel Pg, and an emission area of the blue light-emitting diode LEDb may correspond to the green sub-pixel Pg.

The arrangement of the red sub-pixel Pr, the green sub-pixel Pg, and the blue sub-pixel Pb described with reference to FIG. 5A by using the first to third imaginary quadrangles VQA1, VQA2, and VQA3 is substantially identical to the arrangement of the red light-emitting diode LEDr, the green light-emitting diode LEDg, and the blue light-emitting diode LEDb shown in FIG. 5B.

The red light-emitting diode LEDr and the blue light-emitting diode LEDb may each be arranged at a vertex of the first imaginary quadrangle VQA1 centered on the green light-emitting diode LEDg. In an embodiment, for example, two red light-emitting diodes LEDr may be respectively arranged at opposite vertices in the first diagonal direction ob1 of the first imaginary quadrangle VQA1 with the green light-emitting diode LEDg therebetween. Two blue light-emitting diodes LEDb may be respectively arranged at opposite vertices in the second diagonal direction ob2 of the first imaginary quadrangle VQA1 with the green light-emitting diode LEDg therebetween.

The green light-emitting diodes LEDg may respectively be arranged at vertices of the second imaginary quadrangle VQA2 or the third imaginary quadrangle VQA3, which are centered on the blue light-emitting diode LEDb or the red light-emitting diode LEDr. In an embodiment, as shown in FIG. 5B, four green light-emitting diodes LEDg may be respectively arranged at vertices of the second imaginary quadrangle VQA2 centered on the blue light-emitting diode LEDb. In such an embodiment, four green light-emitting diodes LEDg may be respectively arranged at vertices of the third imaginary quadrangle VQA3 centered on the red light-emitting diode LEDr.

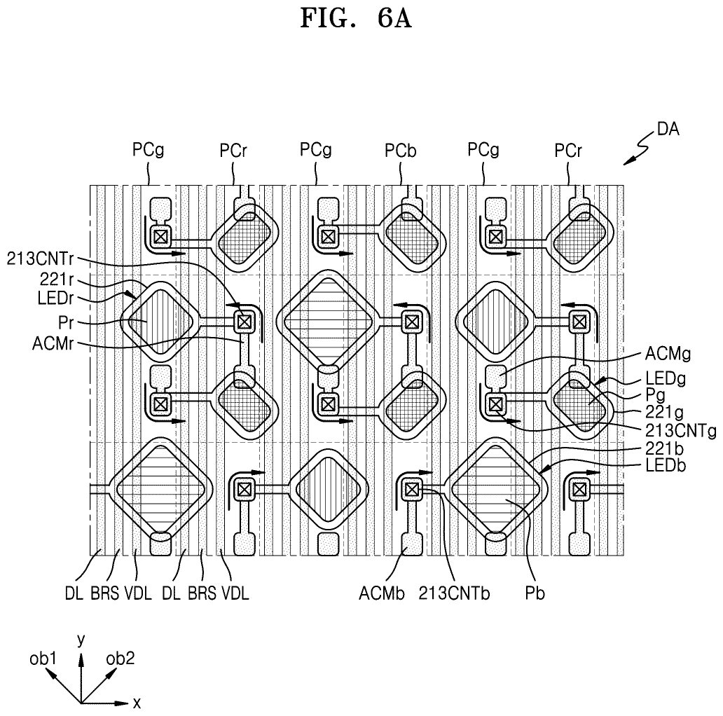

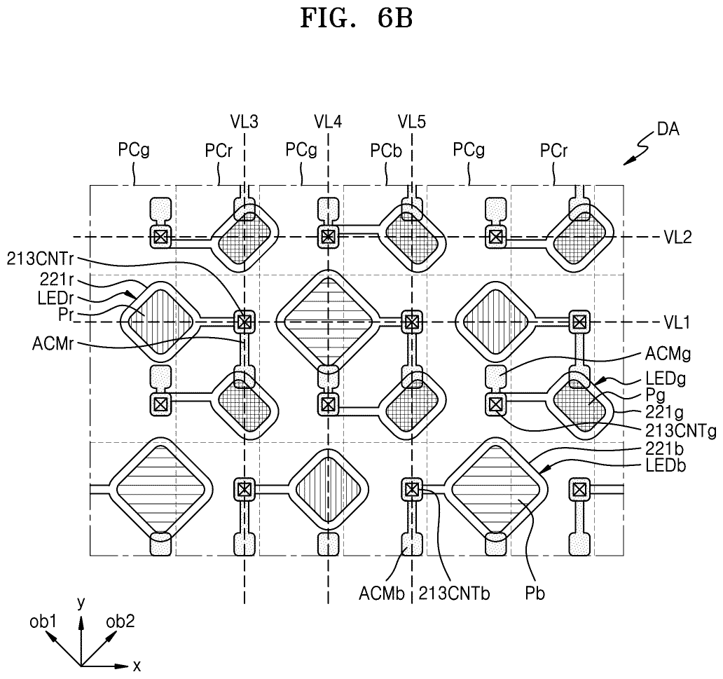

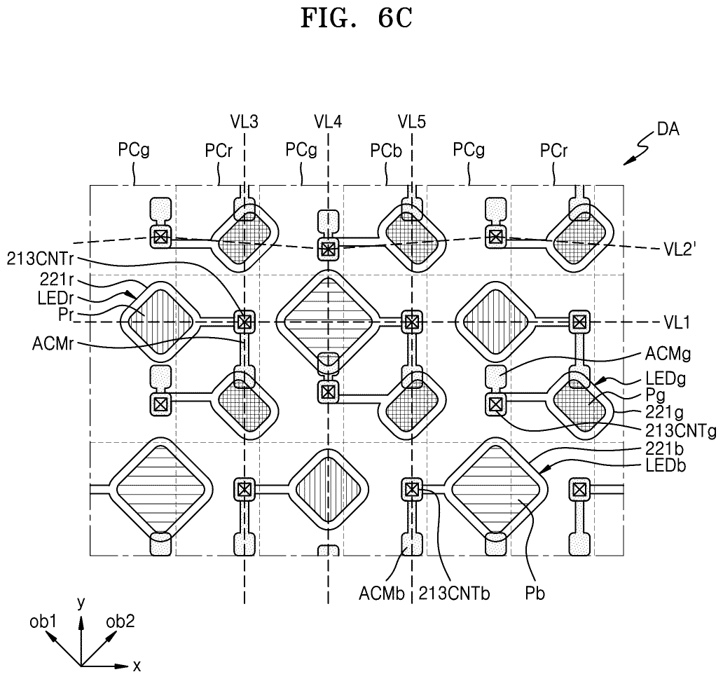

FIG. 6A is a plan view illustrating driving circuits arranged in a display area DA of a display apparatus, lines electrically connected to the driving circuits, and light-emitting diodes, according to an embodiment.

Referring to FIG. 6A, in an embodiment, a first driving circuit PCr electrically connected to the red light-emitting diode LEDr, a second driving circuit PCg electrically connected to the green light-emitting diode LEDg, and a third driving circuit PCb electrically connected to the blue light-emitting diode LEDb may be arranged in the display area DA. Each of the first driving circuit PCr, the second driving circuit PCg, and the third driving circuit PCb may be substantially identical to those described above with reference to FIG. 3. For example, each of the first driving circuit PCr, the second driving circuit PCg, and the third driving circuit PCb may include the transistors and the storage capacitor described with reference to FIG. 3.

The first driving circuits PCr may be arranged in a column direction (e.g., a ±y direction). The second driving circuits PCg may be arranged in the column direction (e.g., the ±y direction), and the third driving circuits PCb may be arranged in the column direction (e.g., ±y direction). In an embodiment, for example, as shown in FIG. 6A, a column of the second driving circuits PCg may be arranged between a column of the first driving circuits PCr and a column of the third driving circuits PCb. In such an embodiment, as shown in FIG. 6A, the column of the first driving circuits PCr, the column of the second driving circuits PCg, the column of the third driving circuits PCb, and the column of the second driving circuits PCg may be repeatedly arranged along the row direction (e.g., ±x direction).

The driving circuits arranged in the respective columns may be electrically connected to the data line DL, a vertical conductive line BRS, and the vertical driving voltage line VDL. In an embodiment, for example, each of the column of the first driving circuits PCr, the column of the second driving circuits PCg, and the column of the third driving circuits PCb may be electrically connected to the data line DL, the vertical conductive line BRS, and the vertical driving voltage line VDL that pass through a corresponding column.

Positions of the data line DL, the vertical conductive line BRS, and the vertical driving voltage line VDL that pass or extend through one column from among the column of the first driving circuits PCr, the column of the second driving circuits PCg, and the column of the third driving circuits PCb may be substantially identical to positions of the data line DL, the vertical conductive line BRS, and the vertical driving voltage line VDL that pass or extend through another one column from among the column of the first driving circuits PCr, the column of the second driving circuits PCg, and the column of the third driving circuits PCb.

The data line DL and the vertical driving voltage line VDL are respectively identical to those described above with reference to FIGS. 3 and 4. The vertical conductive line BRS may be the vertical common voltage line VSL described with reference to FIG. 4, or may be a data connection line for providing a data signal to driving circuits arranged in columns other than a column of driving circuits that the vertical conductive line BRS passes or extends through. In an embodiment, the vertical conductive line BRS that passes or extends through one column may be the vertical common voltage line VSL (see FIG. 4) having a same voltage level as the common voltage supply line 10 as described with reference to FIG. 1 (e.g., a voltage level of constant voltage). In another embodiment, the vertical conductive line BRS that passes or extends through one column may be a data connection line for transmitting a data signal to a data line electrically connected to a driving voltage line arranged in another column.

A first electrode 221r of the red light-emitting diode LEDr may be electrically connected to the corresponding first driving circuit PCr through a first via connection metal ACMr. The first via connection metal ACMr is a configuration corresponding to the via connection metal ACM described above with reference to FIG. 4, and may be disposed under the first electrode 221r with a third insulating layer (e.g., the third organic insulating layer 213 (see FIG. 4)) therebetween. The first electrode 221r of the red light-emitting diode LEDr may be connected to the first via connection metal ACMr via a first via contact hole 213CNTr of the third organic insulating layer 213 (see FIG. 4). The first via contact hole 213CNTr may be a contact (or contact point) of the first electrode 221r of the red light-emitting diode LEDr and the first via connection metal ACMr.

A first electrode 221g of the green light-emitting diode LEDg may be electrically connected to the corresponding second driving circuit PCg through a second via connection metal ACMg. The second via connection metal ACMg is a configuration corresponding to the via connection metal ACM described above with reference to FIG. 4, and may be disposed under the first electrode 221g with the third insulating layer (e.g., the third organic insulating layer 213 (see FIG. 4)) therebetween. The first electrode 221g of the green light-emitting diode LEDg may be connected to the second via connection metal ACMg via a second via contact hole 213CNTg of the third organic insulating layer 213 (see FIG. 4). The second via contact hole 213CNTg may be a contact (or contact point) of the first electrode 221g of the green light-emitting diode LEDg and the second via connection metal ACMg.

A first electrode 221b of the blue light-emitting diode LEDb may be electrically connected to the corresponding third driving circuit PCb through a third via connection metal ACMb. The third via connection metal ACMb is a configuration corresponding to the via connection metal ACM described above with reference to FIG. 4, and may be disposed under the first electrode 221b with the third insulating layer (e.g., the third organic insulating layer 213 (see FIG. 4)) therebetween. The first electrode 221b of the blue light-emitting diode LEDb may be connected to the third via connection metal ACMb via a third via contact hole 213CNTb of the third organic insulating layer 213 (see FIG. 4). The third via contact hole 213CNTb may be a contact (or contact point) of the first electrode 221b of the blue light-emitting diode LEDb and the third via connection metal ACMb.

According to one or more embodiments, through a structure as shown in FIG. 6A, an overlapping area between the vertical conductive line BRS and the first electrodes 221r, 221g, and 221b of the red, green, or blue light-emitting diodes LEDr, LEDg, and LEDb may be minimized, and thus, the coupling therebetween may be substantially reduced or minimized.

Referring to FIGS. 4 and 6A, in an embodiment, the first via connection metal ACMr electrically connected to a sixth transistor of the first driving circuit PCr may extend in the column direction, for example, in the ±y direction. A first end from among both opposing ends of the first via connection metal ACMr may be electrically connected to the sixth transistor of the first driving circuit PCr, and a second end from among both opposing ends of the first via connection metal ACMr may be connected to the first electrode 221r of the red light-emitting diode LEDr.

An emission area of the red light-emitting diode LEDr (or the red sub-pixel Pr) may or may not overlap at least partially with the corresponding first driving circuit PCr, that is, at least a portion of the emission area of the red light-emitting diode LEDr (or the red sub-pixel Pr) may not overlap the corresponding first driving circuit PCr. In an embodiment, as shown in FIG. 6A, an emission area of the red light-emitting diode LEDr electrically connected to one of two adjacent first driving circuits PCr arranged in a same column may partially overlap the corresponding first driving circuit PCr and/or second driving circuit PCg. An emission area of the red light-emitting diode LEDr electrically connected to the other of the two adjacent first driving circuits PCr arranged in a same column may partially overlap a driving circuit other than the corresponding first driving circuit PCr, for example, the second driving circuit PCg and/or the third driving circuit PCb.

Positions of the first via connection metal ACMr in the respective first driving circuits PCr may be identical to each other. First electrodes 221r of two red light-emitting diodes LEDr electrically connected to two adjacent first driving circuits PCr arranged in a same column may extend or be arranged in opposite directions with respect to an imaginary line passing through the first via contact hole 213CNTr and the first via connection metal ACMr.

In an embodiment, for example, the first electrode 221r of the red light-emitting diode LEDr electrically connected to one of two adjacent first driving circuits PCr arranged in a same column may extend in the −x direction from an imaginary line passing through the first via contact hole 213CNTr and the first via connection metal ACMr (e.g., a third imaginary line VL3 described below with reference to FIG. 6B) (see arrows in FIG. 6A). The first electrode 221r of the red light-emitting diode LEDr electrically connected to the other of the two adjacent first driving circuits PCr arranged in a same column may extend in the +x direction from the imaginary line described above (e.g., the third imaginary line VL3 described below with reference to FIG. 6B) (see arrows in FIG. 6A).

Referring to FIGS. 4 and 6A, the second via connection metal ACMg electrically connected to a sixth transistor of the second driving circuit PCg may extend in a column direction, for example, in the ±y direction. A first end from among both opposing ends of the second via connection metal ACMg may be electrically connected to the sixth transistor of the second driving circuit PCg, and a second end from among both opposing ends of the second via connection metal ACMg may be connected to the first electrode 221g of the green light-emitting diode LEDg.

An emission area of the green light-emitting diode LEDg (or the green sub-pixel Pg) may or may not overlap at least partially with the corresponding second driving circuit PCg. In an embodiment, as shown in FIG. 6A, each of the emission areas of the green light-emitting diodes LEDg electrically connected to the respective two adjacent second driving circuits PCg arranged in a same column may not overlap the corresponding second driving circuit PCg, but overlaps another driving circuit, for example, the first driving circuit PCr and/or the third driving circuit PCb.

Positions of the second via connection metal ACMg in the respective second driving circuit PCg may be identical to each other. First electrodes 221g of two green light-emitting diodes LEDg electrically connected to two adjacent second driving circuits PCg arranged in a same column may extend or be arranged in thesame direction with respect to an imaginary line passing through the second via contact hole 213CNTg and the second via connection metal ACMg.

In an embodiment, for example, the first electrode 221g of the green light-emitting diode LEDg electrically connected to one of two adjacent second driving circuits PCg arranged in a same column may extend in the +x direction from an imaginary line passing through the second via contact hole 213CNTg and the second via connection metal ACMg (e.g., a fourth imaginary line VL4 described below with reference to FIG. 6B) (see arrows in FIG. 6A). Likewise, the first electrode 221g of the green light-emitting diode LEDg electrically connected to the other of the two adjacent second driving circuits PCg arranged in the same column may extend in the +x direction from the imaginary line described above (e.g., the fourth imaginary line VL4 described below with reference to FIG. 6B) (see arrows in FIG. 6A).

Referring to FIGS. 4 and 6A, the third via connection metal ACMb electrically connected to a sixth transistor of the third driving circuit PCb may extend in the column direction, for example, in the ±y direction. A first end from among both opposing ends of the third via connection metal ACMb may be electrically connected to the sixth transistor of the third driving circuit PCb, and a second end from among both opposing ends of the third via connection metal ACMb may be connected to the first electrode 221b of the blue light-emitting diode LEDb.

An emission area of the blue light-emitting diode LEDb (or the blue sub-pixel Pb) may or may not overlap at least partially with the corresponding third driving circuit PCb. In an embodiment, as shown in FIG. 6A, an emission area of the blue light-emitting diode LEDb electrically connected to one of two adjacent third driving circuits PCb arranged in a same column may partially overlap the corresponding third driving circuit PCb and second driving circuit PCg. An emission area of the blue light-emitting diode LEDb electrically connected to the other of the two adjacent third driving circuits PCb arranged in the same column may partially overlap a driving circuit other than the corresponding third driving circuit PCb, for example, the first driving circuit PCr and/or the second driving circuit PCg.

Positions of the third via connection metal ACMb in the respective third driving circuit PCb may be identical to each other. First electrodes 221b of two blue light-emitting diodes LEDb electrically connected to two adjacent third driving circuits PCb arranged in a same column may extend or be arranged in opposite directions with respect to an imaginary line passing through the third via contact hole 213CNTb and the third via connection metal ACMb.

In an embodiment, for example, the first electrode 221b of the blue light-emitting diode LEDb electrically connected to one of two adjacent third driving circuits PCb arranged in a same column may extend in the −x direction from an imaginary line passing through the third via contact hole 213CNTb and the third via connection metal ACMb (e.g., a fifth imaginary line VL5 described below with reference to FIG. 6B) (see arrows in FIG. 6A). In such an embodiment, the first electrode 221b of the blue light-emitting diode LEDb electrically connected to the other of the two adjacent third driving circuits PCb arranged in the same column may extend in the +x direction from the imaginary line described above (e.g., the fifth imaginary line VL5 described below with reference to FIG. 6B) (see arrows in FIG. 6A).

In some embodiments, each of the first via connection metal ACMr, a second via connection metal ACMg, and the third via connection metal ACMb may extend in the column direction (e.g., the ±y direction). In an embodiment, for example, the first via connection metal ACMr may extend in one direction (e.g., the −y direction) from the first via contact hole 213CNTr, which is a contact with the first electrode 221r of the red light-emitting diode LEDr. The second via connection metal ACMg may extend in the opposite direction (e.g., the +y direction) of the one direction described above, from the second via contact hole 213CNTg, which is a contact with the first electrode 221g of the green light-emitting diode LEDg. The third via connection metal ACMb may extend in the one direction (e.g., the −y direction) from the third via contact hole 213CNTb, which is a contact with the first electrode 221b of the blue light-emitting diode LEDb.

Two second driving circuits PCg arranged in a same column may be respectively connected to the second via connection metal ACMg that extends in the −y direction and the first electrode 221g of the green light-emitting diode LEDg that extends in the +x direction from the second via contact hole 213CNTg (see counterclockwise arrows in FIG. 6A).

One of two third driving circuits PCb arranged in the same column may be electrically connected to the third via connection metal ACMb that extends in the +y direction and the first electrode 221b of the blue light-emitting diode LEDb extending in the −x direction from the third via contact hole 213CNTb (see counterclockwise arrows in FIG. 6A). The other of the two third driving circuits PCb may be electrically connected to the third via connection metal ACMb that extends in the +y direction and the first electrode 221b of the blue light-emitting diode LEDb extending in the +x direction from the third via contact hole 213CNTb (see clockwise arrows in FIG. 6A).

One of two first driving circuit PCr arranged in a same column may be electrically connected to the first via connection metal ACMr that extends in the +y direction and the first electrode 221r of the red light-emitting diode LEDr extending in the −x direction from the first via contact hole 213CNTr (see counterclockwise arrows in FIG. 6A). The other of the two first driving circuits PCr may be electrically connected to the first via connection metal ACMr that extends in the +y direction and the first electrode 221r of the red light-emitting diode LEDr extending in the +x direction from the first via contact hole 213CNTr (see clockwise arrows in FIG. 6A).

FIG. 6B is a plan view illustrating light-emitting diodes and via connection metals that are arranged in the display area DA of the display apparatus shown in FIG. 6A, according to an embodiment. FIG. 6B shows the red, green, and blue light-emitting diodes LEDr, LEDg, and LEDb and the first to third via connection metals ACMr, ACMg, and ACMb in FIG. 6A.

Referring to FIG. 6B, in an embodiment, a first contact of the first electrode 221r of the red light-emitting diode LEDr and the first via connection metal ACMr, for example, the first via contact hole 213CNTr, may be arranged (or defined) between the corresponding red sub-pixel Pr and the blue sub-pixel Pb adjacent to the red sub-pixel Pr described above, in the row direction (e.g., the +x direction). The first contact, for example, the first via contact hole 213CNTr, may be arranged in a space between the red sub-pixel Pr and the blue sub-pixel Pb adjacent to each other in the row direction (e.g., the +x direction).

In an embodiment, the first via contact hole 213CNTr may be arranged between (e.g., directly arranged between) an emission area of the corresponding red light-emitting diode LEDr (e.g., the red sub-pixel Pr) and an emission area of the blue light-emitting diode LEDb (e.g., the blue sub-pixel Pb) adjacent to the red light-emitting diode LEDr in the row direction (+x direction).

A second contact of the first electrode 221g of the green light-emitting diode LEDg and the second via connection metal ACMg, for example, the second via contact hole 213CNTg, may be arranged between the red sub-pixel Pr and the blue sub-pixel Pb adjacent to each other in the column direction (e.g., the ±y direction) with the corresponding green sub-pixel Pg therebetween. The second contact, for example, the second via contact hole 213CNTg, may be arranged in a space between the red sub-pixel Pr and the blue sub-pixel Pb adjacent to each other in the column direction (e.g., the ±y direction).

In an embodiment, the second via contact hole 213CNTg may be arranged between (e.g., directly arranged between) an emission area of the red light-emitting diode LEDr and an emission area of the blue light-emitting diode LEDb adjacent to each other with the green light-emitting diode LEDg therebetween.

A third contact of the first electrode 221b of the blue light-emitting diode LEDb and the third via connection metal ACMb, for example, the third via contact hole 213CNTb, may be arranged between the corresponding blue sub-pixel Pb and the red sub-pixel Pr adjacent to the blue sub-pixel Pb described above, in the row direction (e.g., the ±x direction). The third contact, for example, the third via contact hole 213CNTb, may be arranged in a space between the blue sub-pixel Pb and the red sub-pixel Pr adjacent to each other in the row direction (e.g., the ±x direction).

In an embodiment, the third via contact hole 213CNTb may be arranged between (e.g., directly arranged between) an emission area of the corresponding blue light-emitting diode LEDb (e.g., the blue sub-pixel Pb) and an emission area of the red light-emitting diode LEDr (e.g., the red sub-pixel Pr) adjacent to the blue light-emitting diode LEDb in the row direction (e.g., the ±x direction).

The first via contact hole 213CNTr and the third via contact hole 213CNTb may be alternately arranged in the row direction (e.g., the ±x direction). The first via contact hole 213CNTr and the third via contact hole 213CNTb may be positioned on a first imaginary line VL1 that extends in the row direction (e.g., the ±x direction). The first imaginary line VL1 may pass through the red sub-pixel Pr and the blue sub-pixel Pb. In some embodiments the first imaginary line VL1 may pass through a center of each of the red sub-pixel Pr and the blue sub-pixel Pb.

The second via contact holes 213CNTg may be positioned on a second imaginary line VL2 that extends in the row direction (e.g., the ±x direction). The second imaginary line VL2 may pass through the green sub-pixels Pg. In some embodiments, the second imaginary line VL2 may pass through a center of each of the green sub-pixels Pg.

The first via contact holes 213CNTr may be disposed on a third imaginary line VL3 that extends in the column direction (e.g., the ±y direction). The third imaginary line VL3 may pass through the green sub-pixels Pg arranged in the column direction. In some embodiments, the third imaginary line VL3 may pass through centers of the green sub-pixels Pg arranged in the column direction.

The second via contact holes 213CNTg may be disposed on a fourth imaginary line VL4 that extends in the column direction (e.g., the ±y direction). The fourth imaginary line VL4 may pass through the red sub-pixel Pr and the blue sub-pixel Pb. In some embodiments the fourth imaginary line VL4 may pass through a center of each of the red sub-pixel Pr and the blue sub-pixel Pb.

The third via contact hole 213CNTb may be disposed on a fifth imaginary line VL5 that extends in the column direction (e.g., the ±y direction). The fifth imaginary line VL5 may pass through the green sub-pixels Pg arranged in the column direction. In some embodiments, the fifth imaginary line VL5 may pass through centers of the green sub-pixels Pg arranged in the column direction.

The first via connection metals ACMr may be disposed on a same imaginary line, for example, on the third imaginary line VL3. The second via connection metal ACMg may be disposed on a same imaginary line, for example, on the fourth imaginary line VL4. The third via connection metal ACMb may be disposed on a same imaginary line, for example, on the fifth imaginary line VL5.

In an embodiment, as shown in FIG. 6B, the first to fifth imaginary lines VL1, VL2, VL3, VL4, and VL5 are straight lines. However, one or more embodiments are not limited thereto. In another embodiment, for example, at least one selected from among the first to fifth imaginary lines VL1, VL2, VL3, VL4, and VL5 may be a zigzag line. In such an embodiment, via contact holes arranged in a same row or column may be arranged in a zigzag shape or manner.

FIG. 6C is a plan view illustrating light-emitting diodes and via connection metals that are arranged in a display area DA of a display apparatus, according to an embodiment.

Referring to FIG. 6C, in an embodiment, the first and third to fifth imaginary lines VL1, VL3, VL4, and VL5 may be straight lines, as described above with reference to FIG. 6B. In some embodiments, a second imaginary line VL2′ may be a zigzag line, as shown in FIG. 6C. In an embodiment, for example, the second via contact holes 213CNTg arranged in the row direction (e.g., the ±x direction) may be positioned on the zigzag second imaginary line VL2′. The second imaginary line VL2′ may pass through the green sub-pixels Pg.

In an embodiment, as shown in FIG. 6C, the second imaginary line VL2′ is a zigzag line. However, in another embodiment, at least one selected from the first and third to fifth imaginary lines VL1, VL3, VL4, and VL5 may be a zigzag line.

According to one or more embodiments, through a structure as described with reference to FIGS. 6A to 6C, a space between sub-pixels or first electrodes of a light-emitting diode may be efficiently used to implement a high-resolution display apparatus, and an overlapping area between the vertical conductive line BRS (e.g., a data connection line) and the first electrode of the light-emitting diode may be reduced such that coupling between the vertical conductive line BRS and the first electrode of the light-emitting diode may be substantially reduced.

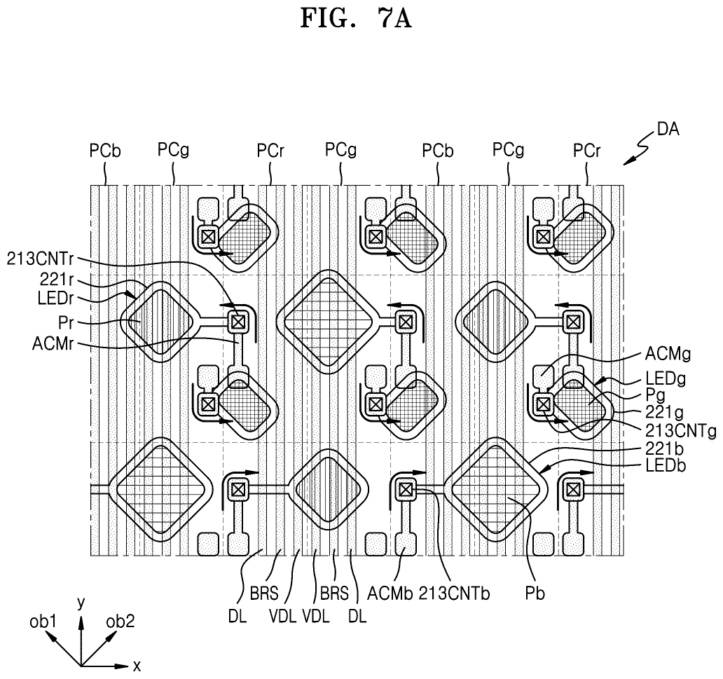

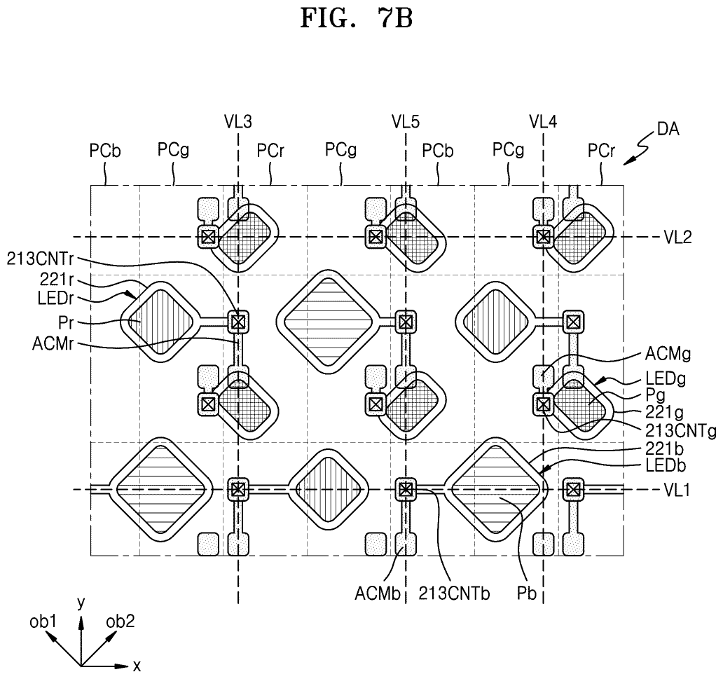

FIG. 7A is a plan view illustrating driving circuits arranged in a display area DA of a display apparatus, lines electrically connected to the driving circuits, and light-emitting diodes, according to an embodiment.

Referring to FIG. 7A, in an embodiment, the first driving circuits PCr electrically connected to the red light-emitting diode LEDr may be arranged in the column direction (e.g., the ±y direction). The second driving circuits PCg electrically connected to the green light-emitting diode LEDg may be arranged in the column direction (e.g., the ±y direction). The third driving circuits PCb electrically connected to the blue light-emitting diode LEDb may be arranged in the column direction (e.g., the ±y direction). In an embodiment, for example, as shown in FIG. 7A, a column of the second driving circuits PCg may be arranged between a column of the first driving circuits PCr and a column of the third driving circuits PCb. In such an embodiment, as shown in FIG. 7A, the column of the first driving circuits PCr, the column of the second driving circuits PCg, the column of the third driving circuits PCb, and the column of the second driving circuits PCg may be repeatedly arranged along a row direction.

The driving circuits arranged in the respective columns may be electrically connected to the data line DL, a vertical conductive line BRS, and the vertical driving voltage line VDL. In an embodiment, for example, each of the column of the first driving circuits PCr, the column of the second driving circuits PCg, and the column of the third driving circuits PCb may be electrically connected to the data line DL, the vertical conductive line BRS, and the vertical driving voltage line VDL that pass through a corresponding column.

Positions of the data line DL, the vertical conductive line BRS, and the vertical driving voltage line VDL passing through one column of the driving circuits and positions of the data line DL, the vertical conductive line BRS, and the vertical driving voltage line VDL passing through a column of adjacent driving circuits may be symmetrical to each other about an imaginary axis passing through columns of driving circuits adjacent to each other. In an embodiment, for example, positions of the data line DL, the vertical conductive line BRS, and the vertical driving voltage line VDL passing through each of a column of first driving circuits PCr and a column of second driving circuits PCg adjacent to each other may be (reflectively) symmetrical to each other about an imaginary axis between a column of first driving circuits PCr and a column of second driving circuits PCg adjacent to each other.

The first electrode 221r of the red light-emitting diode LEDr may be electrically connected to the corresponding first driving circuit PCr through the first via connection metal ACMr. The first electrode 221g of the green light-emitting diode LEDg may be electrically connected to the corresponding second driving circuit PCg through the second via connection metal ACMg. The first electrode 221b of the blue light-emitting diode LEDb may be electrically connected to the corresponding third driving circuit PCb through the third via connection metal ACMb.

The first via connection metal ACMr electrically connected to the first driving circuit PCr may extend in the column direction, for example, in the ±y direction. A first end from among both opposing ends of the first via connection metal ACMr may be electrically connected to the sixth transistor of the first driving circuit PCr, and a second end from among both opposing ends of the first via connection metal ACMr may be connected to the first electrode 221r of the red light-emitting diode LEDr.

An emission area of the red light-emitting diode LEDr (or the red sub-pixel Pr) may or may not overlap at least partially with the corresponding first driving circuit PCr. In an embodiment, as shown in FIG. 7A, an emission area of the red light-emitting diode LEDr electrically connected to one of two adjacent first driving circuits PCr arranged in the same column may partially overlap the corresponding first driving circuit PCr and/or second driving circuit PCg. An emission area of the red light-emitting diode LEDr electrically connected to the other of the two adjacent first driving circuits PCr arranged in the same column may overlap a driving circuit other than the corresponding first driving circuit PCr, for example, the second driving circuit PCg and/or the third driving circuit PCb.

Positions of the first via connection metal ACMr in the respective first driving circuits PCr may be identical to each other. First electrodes 221r of two red light-emitting diodes LEDr electrically connected to two adjacent first driving circuits PCr arranged in a same column may extend or be arranged in opposite directions with respect to an imaginary line passing through the first via contact hole 213CNTr and the first via connection metal ACMr.

The first via connection metals ACMr may be disposed on an imaginary line (e.g., the third imaginary line VL3 described below with reference to FIG. 7B). The first electrode 221r of the red light-emitting diode LEDr electrically connected to one of two adjacent first driving circuits PCr arranged in a same column may extend in the −x direction from an imaginary line passing through the first via contact hole 213CNTr and the first via connection metal ACMr (e.g., a third imaginary line VL3 described below with reference to FIG. 7B) (see arrows in FIG. 7A). The first electrode 221r of the red light-emitting diode LEDr electrically connected to the other of the two adjacent first driving circuits PCr described above may extend in the +x direction from the imaginary line described above (e.g., the third imaginary line VL3 described below with reference to FIG. 7B) (see arrows in FIG. 7A).

The second via connection metal ACMg electrically connected to the sixth transistor of the second driving circuit PCg may extend in the column direction, for example, the ±y direction. A first end from among both opposing ends of the second via connection metal ACMg may be electrically connected to the sixth transistor of the second driving circuit PCg, and a second end from among both opposing ends of the second via connection metal ACMg may be connected to the first electrode 221g of the green light-emitting diode LEDg.

An emission area of the green light-emitting diode LEDg (or the green sub-pixel Pg) may or may not overlap at least partially with the corresponding second driving circuit PCg. In an embodiment, as shown in FIG. 7A, each of the emission areas of the green light-emitting diodes LEDg electrically connected to the respective two adjacent second driving circuits PCg arranged in a same column may partially overlap the corresponding second driving circuit PCg.

Positions of the second via connection metal ACMg in the respective second driving circuit PCg may be identical to each other. First electrodes 221g of two green light-emitting diodes LEDg electrically connected to two adjacent second driving circuits PCg arranged in a same column may extend or be arranged in the same direction with respect to an imaginary line passing through the second via contact hole 213CNTg and the second via connection metal ACMg.

In an embodiment, for example, the first electrode 221g of the green light-emitting diode LEDg electrically connected to one of two adjacent second driving circuits PCg arranged in a same column may extend in the +x direction from an imaginary line passing through the second via contact hole 213CNTg and the second via connection metal ACMg (e.g., a fourth imaginary line VL4 described below with reference to FIG. 7B) (see arrows in FIG. 7A). In such an embodiment, the first electrode 221g of the green light-emitting diode LEDg electrically connected to the other of the two adjacent second driving circuits PCg arranged in the same column may extend in the +x direction from the imaginary line described above (e.g., the fourth imaginary line VL4 described below with reference to FIG. 7B) (see arrows in FIG. 7A).

The third via connection metal ACMb electrically connected to the sixth transistor of the third driving circuit PCb may extend in the column direction, for example, the ±y direction. A first end from among both opposing ends of the third via connection metal ACMb may be electrically connected to the sixth transistor of the third driving circuit PCb, and a second end from among both opposing ends of the third via connection metal ACMb may be connected to the first electrode 221b of the blue light-emitting diode LEDb.

An emission area of the blue light-emitting diode LEDb (or the blue sub-pixel Pb) may or may not overlap at least partially with the corresponding third driving circuit PCb. In an embodiment, as shown in FIG. 7A, an emission area of the blue light-emitting diode LEDb electrically connected to one of two adjacent third driving circuits PCb arranged in a same column may partially overlap the corresponding third driving circuit PCb and/or second driving circuit PCg. An emission area of the blue light-emitting diode LEDb electrically connected to the other of the two adjacent third driving circuits PCb arranged in the same column may partially overlap a driving circuit other than the corresponding third driving circuit PCb, for example, the second driving circuit PCg and/or the first driving circuit PCr.

Positions of the third via connection metal ACMb in the respective third driving circuit PCb may be identical to each other. First electrodes 221b of two blue light-emitting diodes LEDb electrically connected to two adjacent third driving circuits PCb arranged in the same column may extend or be arranged in opposite directions with respect to an imaginary line passing through the third via contact hole 213CNTb and the third via connection metal ACMb.

In an embodiment, for example, the first electrode 221b of the blue light-emitting diode LEDb electrically connected to one of two adjacent third driving circuits PCb arranged in a same column may extend in the −x direction from an imaginary line passing through the third via contact hole 213CNTb and the third via connection metal ACMb (e.g., the fifth imaginary line VL5 described below with reference to FIG. 7B) (see arrows in FIG. 7A). In such an embodiment, the first electrode 221b of the blue light-emitting diode LEDb electrically connected to the other of the two adjacent third driving circuits PCb arranged in the same column may extend in the +x direction from the imaginary line described above (e.g., the fifth imaginary line VL5 described below with reference to FIG. 7B) (see arrows in FIG. 7A).

In some embodiments, each of the first via connection metal ACMr, the second via connection metal ACMg, and the third via connection metal ACMb may extend in the column direction (e.g., the ±y direction). In an embodiment, for example, the first via connection metal ACMr may extend in one direction (e.g., the −y direction) from the first via contact hole 213CNTr, which is a contact with the first electrode 221r of the red light-emitting diode LEDr. The second via connection metal ACMg may extend in the opposite direction (e.g., the +y direction) of the one direction described above, from the second via contact hole 213CNTg, which is a contact with the first electrode 221g of the green light-emitting diode LEDg. The third via connection metal ACMb may extend in the one direction (e.g., the −y direction) from the third via contact hole 213CNTb, which is a contact with the first electrode 221b of the blue light-emitting diode LEDb.

One of two first driving circuit PCr arranged in the same column may be electrically connected to the first via connection metal ACMr that extends in the +y direction and the first electrode 221r of the red light-emitting diode LEDr extending in the −x direction from the first via contact hole 213CNTr (see counterclockwise arrows in FIG. 7A). The other of the two first driving circuits PCr may be electrically connected to the first via connection metal ACMr that extends in the +y direction and the first electrode 221r of the red light-emitting diode LEDr extending in the +x direction from the first via contact hole 213CNTr (see clockwise arrows in FIG. 7A).

Two second driving circuits PCg arranged in a same column may be respectively connected to the second via connection metal ACMg that extends in the −y direction and the first electrode 221g of the green light-emitting diode LEDg that extends in the +x direction from the second via contact hole 213CNTg (see counterclockwise arrows in FIG. 7A).

One of two third driving circuits PCb arranged in a same column may be electrically connected to the third via connection metal ACMb that extends in the +y direction and the first electrode 221b of the blue light-emitting diode LEDb extending in the −x direction from the third via contact hole 213CNTb (see counterclockwise arrows in FIG. 7A). The other of the two third driving circuits PCb may be electrically connected to the third via connection metal ACMb that extends in the +y direction and the first electrode 221b of the blue light-emitting diode LEDb extending in the −x direction from the third via contact hole 213CNTb (see clockwise arrows in FIG. 7A).

FIG. 7B is a plan view illustrating light-emitting diodes and via connection metals that are arranged in the display area DA of the display apparatus shown in FIG. 7A, according to an embodiment. FIG. 7B shows the red, green, and blue light-emitting diodes LEDr, LEDg, and LEDb and the first to third via connection metals ACMr, ACMg, and ACMb in FIG. 7A.

Referring to FIG. 7B, in an embodiment, a first contact of the first electrode 221r of the red light-emitting diode LEDr and the first via connection metal ACMr, for example, the first via contact hole 213CNTr, may be arranged between the corresponding red sub-pixel Pr and the blue sub-pixel Pb adjacent to the red sub-pixel Pr described above, in the row direction (e.g., the ±x direction). The first contact, for example, the first via contact hole 213CNTr, may be arranged in a space between the red sub-pixel Pr and the blue sub-pixel Pb adjacent to each other in the row direction (e.g., the ±x direction).

In an embodiment, the first via contact hole 213CNTr may be arranged between (e.g., directly arranged between) an emission area of the corresponding red light-emitting diode LEDr (e.g., the red sub-pixel Pr) and an emission area of the blue light-emitting diode LEDb (e.g., the blue sub-pixel Pb) adjacent to the red light-emitting diode LEDr in the row direction (e.g., the ±x direction).

A second contact of the first electrode 221g of the green light-emitting diode LEDg and the second via connection metal ACMg, for example, the second via contact hole 213CNTg, may be arranged between the red sub-pixel Pr and the blue sub-pixel Pb adjacent to each other in the column direction (e.g., the ±y direction) with the corresponding green sub-pixel Pg therebetween. The second contact, for example, the second via contact hole 213CNTg, may be arranged in a space between the red sub-pixel Pr and the blue sub-pixel Pb adjacent to each other in the column direction (e.g., the ±y direction).

In an embodiment, the second via contact hole 213CNTg may be arranged between the red light-emitting diode LEDr and the blue light-emitting diode LEDb adjacent to each other in the column direction (e.g., the ±y direction) with the green light-emitting diode LEDg described above, therebetween.

A third contact of the first electrode 221b of the blue light-emitting diode LEDb and the third via connection metal ACMb, for example, the third via contact hole 213CNTb may be arranged between the corresponding blue sub-pixel Pb and the red sub-pixel Pr adjacent to the blue sub-pixel Pb described above, in the row direction (e.g., the ±x direction). The third contact, for example, the third via contact hole 213CNTb, may be arranged in a space between the blue sub-pixel Pb and the red sub-pixel Pr adjacent to each other in the row direction (e.g., the ±x direction).

In an embodiment, the third via contact hole 213CNTb may be arranged between (e.g., directly arranged between) an emission area of the corresponding blue light-emitting diode LEDb (e.g., the blue sub-pixel Pb) and an emission area of the red light-emitting diode LEDr (e.g., the red sub-pixel Pr) adjacent to the blue light-emitting diode LEDb in the row direction (e.g., the ±x direction).

The first via contact hole 213CNTr and the third via contact hole 213CNTb may be alternately arranged in the row direction (e.g., the ±x direction). The first via contact hole 213CNTr and the third via contact hole 213CNTb may be positioned on a first imaginary line VL1 that extends in the row direction (e.g., the ±x direction). The first imaginary line VL1 may pass through the red sub-pixel Pr and the blue sub-pixel Pb. In some embodiments the first imaginary line VL1 may pass through a center of each of the red sub-pixel Pr and the blue sub-pixel Pb.

The second via contact holes 213CNTg may be positioned on a second imaginary line VL2 that extends in the row direction (e.g., the ±x direction). The second imaginary line VL2 may pass through the green sub-pixels Pg. In some embodiments, the second imaginary line VL2 may pass through a center of each of the green sub-pixels Pg.

The first via contact holes 213CNTr may be disposed on a third imaginary line VL3 that extends in the column direction (e.g., the ±y direction). The third imaginary line VL3 may pass through the green sub-pixels Pg arranged in the column direction. In some embodiments, the third imaginary line VL3 may be offset in one direction (e.g., the −x direction or +x direction) from centers of the green sub-pixels Pg arranged in the column direction.

The second via contact holes 213CNTg may be disposed on the fourth imaginary line VL4 that extends in the column direction (e.g., the ±y direction). The fourth imaginary line VL4 may pass through the red sub-pixel Pr and the blue sub-pixel Pb. In some embodiments, the fourth imaginary line VL4 may not pass through a sub-pixel.

The third via contact hole 213CNTb may be disposed on the fifth imaginary line VL5 that extends in the column direction (e.g., the ±y direction). The fifth imaginary line VL5 may pass through the green sub-pixels Pg arranged in the column direction. In some embodiments, the fifth imaginary line VL5 may be offset (or spaced apart) in one direction (e.g., the −x direction or +x direction) from the centers of the green sub-pixels Pg arranged in the column direction.

The first via connection metals ACMr may be disposed on the same imaginary line, for example, on the third imaginary line VL3. The second via connection metal ACMg may be disposed on a same imaginary line, for example, on the fourth imaginary line VL4. The third via connection metal ACMb may be disposed on a same imaginary line, for example, on the fifth imaginary line VL5.

In an embodiment, as shown in FIG. 7B, the first to fifth imaginary lines VL1, VL2, VL3, VL4, and VL5 are straight lines. However, one or more embodiments are not limited thereto. As described above with reference to FIG. 6C, at least one selected from among the first to fifth imaginary lines VL1, VL2, VL3, VL4, and VL5 may be a zigzag line. In other words, via contact holes arranged in a same row or column may be arranged in a zigzag shape.

According to one or more embodiments, through a structure as described with reference to FIGS. 7A and 7B, a space between sub-pixels or first electrodes of a light-emitting diode may be efficiently used to implement a high-resolution display apparatus, and an overlapping area between the vertical conductive line BRS (e.g., a data connection line) and the first electrode of the light-emitting diode may be minimized such that coupling between the vertical conductive line BRS and the first electrode of the light-emitting diode may be substantially reduced or minimized.

According to an embodiment, a high-resolution display apparatus may be provided by efficiently utilizing a space, and undesired parasitic capacitance may be reduced. The scope of the one or more embodiments is not limited by these effects.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a first first light-emitting diode which emits light of a first color;
a first second light-emitting diode which emits light of a second color;
a first third light-emitting diode which emits light of a third color, wherein the first first light-emitting diode and the first third light-emitting diode are arranged at two vertices adjacent to each other in a row direction from among vertices of an imaginary quadrangle centered on the first second light-emitting diode;
a first first driving circuit electrically connected to the first first light-emitting diode and comprising a transistor electrically connected to a first data line extending in a column direction crossing the row direction;
a first second driving circuit electrically connected to the first second light-emitting diode and comprising a transistor electrically connected to a second data line extending in the column direction;
a first third driving circuit electrically connected to the first third light-emitting diode and comprising a transistor electrically connected to a third data line extending in the column direction;
a first first via connection metal which electrically connects a first electrode of the first first light-emitting diode and the first first driving circuit to each other;
a first second via connection metal which electrically connects a first electrode of the first second light-emitting diode and the first second driving circuit to each other; and
a first third via connection metal which electrically connects a first electrode of the first third light-emitting diode and the first third driving circuit to each other,
wherein a first contact of the first electrode of the first first light-emitting diode and the first first via connection metal is positioned between an emission area of the first first light-emitting diode and an emission area of the first third light-emitting diode adjacent to each other in the row direction, and
a second contact of the first electrode of the first second light-emitting diode and the first second via connection metal is positioned between an emission area of a second third light-emitting diode and the emission area of the first first light-emitting diode, wherein the second third light-emitting diode is adjacent to the first first light-emitting diode in the column direction and emits light of the third color.

2. The display apparatus of claim 1, wherein the first first driving circuit, the first second driving circuit, and the first third driving circuit are arranged in different columns from one another.

3. The display apparatus of claim 1, further comprising:
a second first light-emitting diode which emits light of the first color and is arranged on an opposite side of the first first light-emitting diode with the first second light-emitting diode therebetween, wherein the first second light-emitting diode is positioned on a center of the imaginary quadrangle,
wherein a second first driving circuit electrically connected to the second first light-emitting diode is arranged in a column in which the first first driving circuit is arranged.

4. The display apparatus of claim 3, wherein the first electrode of the first first light-emitting diode extends in a first direction with respect to an imaginary line passing through the first contact in the column direction, and
a first electrode of the second first light-emitting diode extends in a direction opposite to the first direction with respect to the imaginary line.

5. The display apparatus of claim 3, further comprising:
a second second light-emitting diode which is adjacent to the first second light-emitting diode in the row direction and emits light of the second color;
a second second driving circuit electrically connected to the second second light-emitting diode; and
a second second via connection metal which electrically connects the second second light-emitting diode and the second second driving circuit to each other,
wherein a third contact of a first electrode of the second second light-emitting diode and the second second via connection metal is positioned between the emission area of the first third light-emitting diode and an emission area of the second first light-emitting diode.

6. The display apparatus of claim 5, wherein the first second driving circuit and the second second driving circuit are arranged in different columns from each other.

7. The display apparatus of claim 5, wherein the second contact and the third contact are positioned on an imaginary straight line which extends in the row direction.

8. The display apparatus of claim 5, wherein the second contact and the third contact are positioned on an imaginary zigzag line which extends in the row direction.

9. The display apparatus of claim 1, wherein the first first via connection metal extends in a second direction from the first contact, and
the first second via connection metal extends in a direction opposite to the second direction from the second contact.

10. The display apparatus of claim 9, wherein a fourth contact of the first electrode of the first third light-emitting diode and the first third via connection metal is positioned between the emission area of the first third light-emitting diode and an emission area of a third first light-emitting diode, wherein the third first light-emitting diode is adjacent to the first third light-emitting diode in the row direction and emitting light of the first color.

11. The display apparatus of claim 10, wherein the first third via connection metal extends in the second direction from the fourth contact.

12. A display apparatus comprising:
a first data line, a second data line, and a third data line, wherein each of the first data line, the second data line, and the third data line extends in a column direction;
first driving circuits arranged in the column direction and electrically connected to the first data line;
second driving circuits arranged in the column direction and electrically connected to the second data line;
third driving circuits arranged in the column direction and electrically connected to the third data line;
a first first light-emitting diode electrically connected to a first first driving circuit, which is one of the first driving circuits, wherein the first first light-emitting diode emits light of a first color;
a second first light-emitting diode electrically connected to a second first driving circuit, which is another of the first driving circuits, wherein the second first light-emitting diode emits light of the first color;
a first second light-emitting diode electrically connected to a first second driving circuit, which is one of the second driving circuits, wherein the first second light-emitting diode emits light of a second color; and
a first third light-emitting diode electrically connected to a first third driving circuit, which is one of the third driving circuits, wherein the first third light-emitting diode emits light of a third color,
wherein the first first light-emitting diode, the second first light-emitting diode, and the first third light-emitting diode are positioned at vertices of an imaginary quadrangle centered on the first second light-emitting diode,
the first first light-emitting diode and the second first light-emitting diode is arranged in a diagonal direction of the imaginary quadrangle with the first second light-emitting diode therebetween,
the first third light-emitting diode is arranged adjacent to the first first light-emitting diode in a row direction crossing the column direction, and
the first first driving circuit and the second first driving circuit are adjacent to each other in the column direction.

13. The display apparatus of claim 12, further comprising:
a first first via connection metal which electrically connects a first electrode of the first first light-emitting diode and the first first driving circuit to each other,
wherein a first contact of the first electrode of the first first light-emitting diode and the first first via connection metal is positioned between the first first light-emitting diode and the first third light-emitting diode adjacent to each other in the row direction.

14. The display apparatus of claim 13, further comprising:
a first second via connection metal which electrically connects a first electrode of the first second light-emitting diode and the first second driving circuit to each other; and
a second third light-emitting diode adjacent to the first first light-emitting diode in the column direction,
wherein a second contact of the first electrode of the first second light-emitting diode and the first second via connection metal is positioned between the first first light-emitting diode and the second third light-emitting diode.

15. The display apparatus of claim 14, further comprising:
a second second light-emitting diode adjacent to the first second light-emitting diode in the row direction; and
a second second via connection metal which electrically connects a first electrode of the second second light-emitting diode and a second second driving circuit to each other.

16. The display apparatus of claim 15, wherein the second contact and a third contact of the first electrode of the second second light-emitting diode and the second second via connection metal are positioned on an imaginary straight line or an imaginary zigzag line extending in the row direction.

17. The display apparatus of claim 13, further comprising:
a second first via connection metal which electrically connects a first electrode of the second first light-emitting diode and the second first driving circuit to each other,
wherein a fourth contact of the first electrode of the second first light-emitting diode and the second first via connection metal, and the first contact are positioned on an imaginary line in the column direction.

18. The display apparatus of claim 17, wherein the first electrode of the first first light-emitting diode extends in a first direction from the imaginary line, and
the first electrode of the second first light-emitting diode extends in a direction opposite to the first direction from the imaginary line.

19. The display apparatus of claim 14, wherein the first first via connection metal extends in a second direction from the first contact, and
the first second via connection metal extends in a direction opposite to the second direction from the second contact.

20. The display apparatus of claim 12, further comprising:
a first third via connection metal which electrically connects a first electrode of the first third light-emitting diode and the first third driving circuit to each other; and
a third first light-emitting diode adjacent to the first third light-emitting diode in the row direction,
wherein a fifth contact of the first electrode of the first third light-emitting diode and the first third via connection metal is positioned between the first third light-emitting diode and the third first light-emitting diode.

21. A display apparatus comprising:
a first first light-emitting diode and a second first light-emitting diode, which emit light of a first color;
a first second light-emitting diode which emits light of a second color;
a first third light-emitting diode which emits light of a third color;
a first first driving circuit electrically connected to a first data line which extends in a column direction, wherein the first first driving circuit comprises transistors;
a first insulating layer disposed on an electrode electrically connected to a semiconductor layer of one transistor from among the transistors of the first first driving circuit;
a connection metal disposed on the first insulating layer and electrically connected to the electrode;
a second insulating layer on the connection metal;
a first first via connection metal disposed on the second insulating layer and electrically connected to the connection metal; and
a third insulating layer on the first first via connection metal,
wherein the first first light-emitting diode, the second first light-emitting diode, and the first third light-emitting diode are positioned at vertices of an imaginary quadrangle centered on the first second light-emitting diode,
the first first light-emitting diode and the second first light-emitting diode are arranged in a diagonal direction of the imaginary quadrangle with the first second light-emitting diode therebetween,
the first third light-emitting diode is arranged adjacent to the first first light-emitting diode in a row direction crossing the column direction,
the first first driving circuit is adjacent to a second first driving circuit in the column direction, and
the second first driving circuit is electrically connected to the second first light-emitting diode.

22. The display apparatus of claim 21, wherein a first electrode of the first first light-emitting diode is disposed on the third insulating layer, and
a first contact of the first electrode of the first first light-emitting diode and the first first via connection metal is positioned between the first first light-emitting diode and the first third light-emitting diode adjacent to each other in the row direction.

23. The display apparatus of claim 21, further comprising:
a first second driving circuit arranged in a column different from a column in which the first first driving circuit is arranged;
a first second via connection metal which electrically connects a first electrode of the first second light-emitting diode and the first second driving circuit to each other; and
a second third light-emitting diode adjacent to the first first light-emitting diode in the column direction,
wherein a second contact of the first electrode of the first second light-emitting diode and the first second via connection metal is positioned between the first first light-emitting diode and the second third light-emitting diode.

24. The display apparatus of claim 23, further comprising:
a second second driving circuit arranged in a column different from the column in which the first second driving circuit is arranged;
a second second light-emitting diode adjacent to the first second light-emitting diode in the row direction; and
a second second via connection metal which electrically connects a first electrode of the second second light-emitting diode and the second second driving circuit to each other.

25. The display apparatus of claim 24, wherein the second contact and a third contact of the first electrode of the second second light-emitting diode and the second second via connection metal are positioned on an imaginary straight line or an imaginary zigzag line extending in the row direction.

26. The display apparatus of claim 21, further comprising a second first via connection metal which electrically connects a first electrode of the second first light-emitting diode and the second first driving circuit to each other,
wherein the first first via connection metal and the second first via connection metal are disposed on an imaginary line in the column direction,
a first electrode of the first first light-emitting diode extends in a first direction from the imaginary line, and
the first electrode of the second first light-emitting diode extends in a direction opposite to the first direction from the imaginary line.

27. The display apparatus of claim 22, further comprising a second first via connection metal which electrically connects a first electrode of the second first light-emitting diode and the second first driving circuit to each other,
wherein a fourth contact of the first electrode of the second first light-emitting diode and the second first via connection metal, and the first contact of the first electrode of the first first light-emitting diode and the first first via connection metal are positioned on an imaginary line in the column direction.

28. The display apparatus of claim 21, further comprising:
a first third driving circuit arranged in a column different from a column in which the first first driving circuit is arranged;
a first third via connection metal which electrically connects a first electrode of the first third light-emitting diode and the first third driving circuit to each other; and
a third first light-emitting diode adjacent to the first third light-emitting diode in the row direction,
wherein a fifth contact of the first electrode of the first third light-emitting diode and the first third via connection metal is positioned between the first third light-emitting diode and the third first light-emitting diode.
